(19) United States
(12) Patent Application Publication
(10) Pub. No.: US 2024/0279538 A1
(43) Pub. Date: Aug. 22, 2024

(54) QUANTUM DOT-CONTAINING COMPLEX, QUANTUM DOT COMPOSITION INCLUDING THE SAME, AND ELECTRONIC APPARATUS INCLUDING THE SAME

(71) Applicant: Samsung Display Co., Ltd., Yongin-si (KR)

(72) Inventors: Kawon Pak, Yongin-si (KR); Joonhyung Kim, Yongin-si (KR)

(73) Assignee: Samsung Display Co., Ltd., Yongin-si (KR)

(21) Appl. No.: 18/459,702

(22) Filed: Sep. 1, 2023

(30) Foreign Application Priority Data
Feb. 6, 2023 (KR) 10-2023-0015727

(51) Int. Cl. C09K 11/02; C09K 11/56; G02F 1/1335; H10K 85/10

(52) U.S. Cl. CPC C09K 11/02; C09K 11/565; G02F 1/133514; H10K 85/111; H10K 85/151

(57) ABSTRACT

Embodiments provide a quantum dot-containing complex including a quantum dot, and ligands A and ligands B. The ligands B are coordinated to a surface of the quantum dot, each of the ligands A include a hydrophilic moiety, a hydrophobic moiety, and a curable moiety, and each of the ligands B include a hydrophobic moisty.

### CROSS-REFERENCE TO RELATED APPLICATION(S)

This application claims priority to and benefits of Korean Patent Application No. 10-2023-0015727 under 35 U.S.C. § 119, filed on Feb. 6, 2023, in the Korean Intellectual Property Office, the entire contents of which are incorporated herein by reference.

### BACKGROUND

### 1. Technical Field

Embodiments relate to a quantum dot-containing complex, a quantum dot composition including the same, and an electronic apparatus including the same.

### 2. Description of the Related Art

Quantum dots are nanocrystals of semiconductor materials and materials exhibiting a quantum confinement effect. When the quantum dots receive light from an excitation source and reach an energy excited state, the quantum dots themselves emit energy according to a corresponding energy band gap. In this regard, even in a case of the same material, as wavelength varies depending on particle size, light of a suitable wavelength band, excellent color purity, and high luminescence efficiency may be obtained by adjusting sizes of quantum dots. Accordingly, quantum dots are applicable to various devices.

Quantum dots may be used as materials that perform various optical functions (for example, a photo-conversion function) of optical members. Quantum dots, as nano-sized semiconductor nanocrystals, may have different energy band gaps by adjusting the size and composition of the nanocrystals, and thus may emit light of various emission wavelengths.

Optical members including such quantum dots may have thin-film forms, for example, a thin-film form in which each subpixel is patterned. The optical members may be used as color conversion members of devices including various light sources.

However, quantum dots may be readily oxidized by moisture and oxygen, and in such cases, efficiency is reduced.

To address this drawback, a method of coordinating reactive ligands around quantum dots has been suggested, but it is difficult to efficiently prevent the oxidation of the quantum dots by desorption, rearrangement, and the like of the ligands.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a quantum dot-containing complex having no defect due to ligand substitution on a surface of a quantum dot, a quantum dot composition including the same, and an electronic apparatus including the same.

Additional aspects will be set forth in part in the description which follows and, in part, will be apparent from the description, or may be learned by practice of the embodiments of the disclosure.

Embodiments provide a quantum dot-containing complex which may include a quantum dot, and ligands A and ligands B, wherein
the ligands B may be coordinated to a surface of the quantum dot,
each of the ligands A may include a hydrophilic moiety, a hydrophobic moiety, and a curable moiety, and
each of the ligands B may include a hydrophobic moiety.

In an embodiment, the hydrophobic moieties of the ligands A and the hydrophobic moieties of the ligands B may be bonded to each other via van der Waals forces.

In an embodiment, the curable moieties of the ligands A may be thermosetting moieties.

In an embodiment, each ligand A may be a compound in which the hydrophilic moiety, the curable moiety, and the hydrophobic moiety are bonded in this order.

In an embodiment, the hydrophilic moiety, the hydrophobic moiety, and the curable moiety of each ligand A may be linked to one another via SP³ carbon bonds.

In an embodiment, the hydrophobic moieties of the ligands B may be coordinated to the surface of the quantum dot.

In an embodiment, the hydrophobic moieties of the ligands A may not be coordinated to the surface of the quantum dot.

In an embodiment, the hydrophobic moieties of the ligands A may face inward toward the quantum dot, and the hydrophilic moieties of the ligands A may face outward from the quantum dot, such that the ligands A form a micelle.

In an embodiment, the curable moieties of the ligands A may be covalently bonded to each other to form a single molecule.

In an embodiment, the hydrophobic moiety of each ligand B may have a length equal to or less than a length of the hydrophobic moiety of each ligand A.

In an embodiment, the ligands A may include a compound represented by one of Formulae 1 to 3:

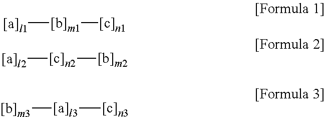

In Formulae 1 to 3,
a may be a group represented by Formula 1-1 or Formula 1-2,

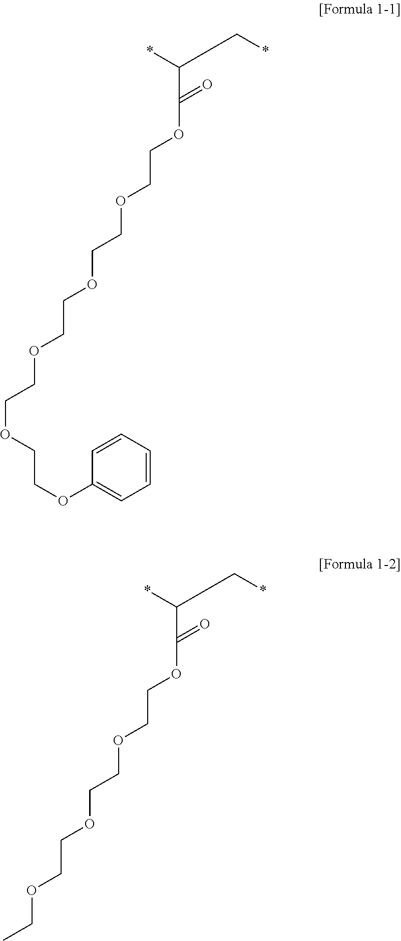 [SMILES: *CCC(*)C(=O)OCCOCCOCCOCCOCCOc1ccccc1 ; *CCC(*)C(=O)OCCOCCOCCOCC]

b may be a group represented by Formula 2-1,

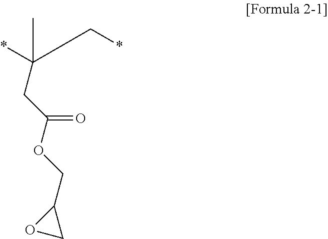 [SMILES: *CCC(*)(C)CC(=O)OCC1CO1]

and c may be a group represented by Formula 3-1, Formula 3-2, or Formula 3-3,

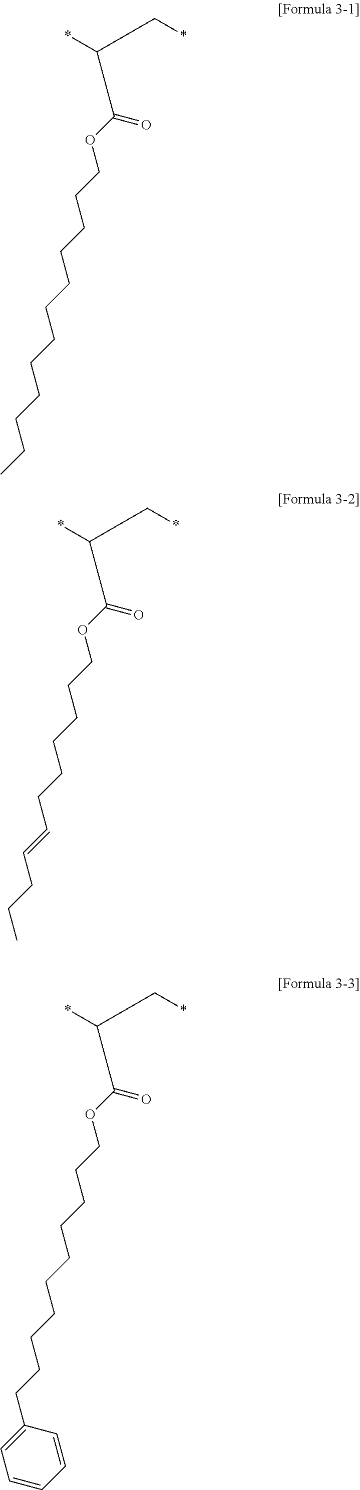 [SMILES: *CCC(*)CC(=O)OCCCCCCCCCCCC ; *CCC(*)CC(=O)OCCCCCC/C=C/CCC ; *CCC(*)CC(=O)OCCCCCCCCCCc1ccccc1]

I1 to I3, m1 to m3, and n1 to n3 may each independently be an integer from 1 to 5,
when I1 is 2 or more, two or more of a in Formula 1 may be identical to or different from each other,
when I2 is 2 or more, two or more of a in Formula 2 may be identical to or different from each other,
when I3 is 2 or more, two or more of a in Formula 3 may be identical to or different from each other,
when n1 is 2 or more, two or more of c in Formula 1 may be identical to or different from each other,
when n2 is 2 or more, two or more of c in Formula 2 may be identical to or different from each other,
when n3 is 2 or more, two or more of c in Formula 3 may be identical to or different from each other, and
in Formulae 1-1, 1-2, 2-1, and 3-1 to 3-3, * denotes a bond, except that * at an end of a molecule denotes hydrogen.
In an embodiment, the quantum dot may have a core-shell structure including a core including a semiconductor compound, and
a shell including an oxide material, a semiconductor compound, or a combination thereof,
wherein the oxide material may include a metal oxide, a metalloid oxide, a non-metal oxide, or a combination thereof.

In an embodiment, the semiconductor compound may include: a Group II-VI semiconductor compound; a Group III-V semiconductor compound; a Group III-VI semiconductor compound; a Group I—III-VI semiconductor compound; a Group IV-VI semiconductor compound; a Group IV element or compound; or any combination thereof.

In an embodiment, the oxide material may include SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, or any combination thereof.

In an embodiment, the semiconductor compound may include CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP, GaS, GaSe, Ga₂Se₃, GaTe, InS, InSe, In₂S₃, In₂Se₃, InTe, InGaS₃, InGaSe₃, AgInS, AgInS₂, CuInS, CuInS₂, CuGaO₂, AgGaO₂, AgAlO₂, AgInGaS, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, SiGe, or any combination thereof.

In an embodiment, the semiconductor compound in the shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

Embodiments provide a quantum dot composition which may include the quantum dot-containing complex.

Embodiments provide an electronic apparatus which may include the quantum dot-containing complex.

In an embodiment, the electronic apparatus may further include a color filter and/or a color conversion layer, wherein the color filter and/or the color conversion layer may include the quantum dot-containing complex.

In an embodiment, the electronic apparatus may further include a light-emitting device including a first electrode, a second electrode facing the first electrode, and an interlayer between the first electrode and the second electrode, wherein the interlayer may include an emission layer, and the emission layer may include the quantum dot-containing complex.

It is to be understood that the embodiments above are described in a generic and explanatory sense only and not for the purposes of limitation, and the disclosure is not limited to the embodiments described above.

### BRIEF DESCRIPTION OF THE DRAWINGS

The above and other aspects, and features of the disclosure will be more apparent by describing in detail embodiments thereof with reference to the accompanying drawings, in which:

FIG. 1A is a schematic view of a structure of a quantum dot-containing complex coordinated with ligands B containing hydrophobic moieties;

FIG. 1B is a schematic view of a structure of a quantum dot-containing complex in which hydrophobic moieties of ligands A are bonded to hydrophobic moieties of ligands B via van der Waals forces, such that the ligands A form a micelle around a quantum dot;

FIG. 1C is a schematic view of a structure in which curable moieties of ligands A are bonded to each other to form a single molecule, thereby encapsulating a quantum dot;

FIG. 2 is a schematic cross-sectional view of a structure of a light-emitting device according to an embodiment;

FIG. 3 is a schematic cross-sectional view of an electronic apparatus according to an embodiment;

FIG. 4 is a schematic cross-sectional view of an electronic apparatus according to another embodiment; and

FIG. 5 is a graph showing the results of stability evaluation of a quantum dot-containing complex according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

### [Quantum Dot-Containing Complex]

For high-efficiency quantum dot synthesis, it is essential to use a non-coordinate solvent having a high boiling point and a hydrophobic ligand. From there, to conduct a subsequent printing process, it is necessary to make quantum dots into ink. To be made into ink, it is necessary to perform a process of substituting hydrophobic ligands of a quantum dot with hydrophilic ligands.

In the process of substituting hydrophobic ligands with hydrophilic ligands, defects may occur as the shell of the quantum dot is torn out together with the ligands. This may lead to permanent defects in the shell of the quantum dot, which results in non-reversibly reduced efficiency.

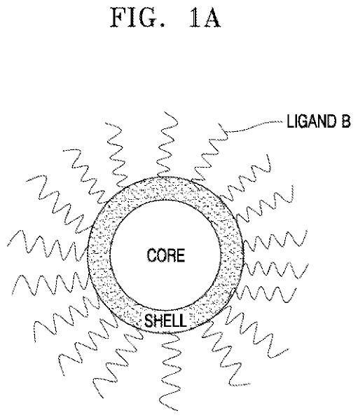

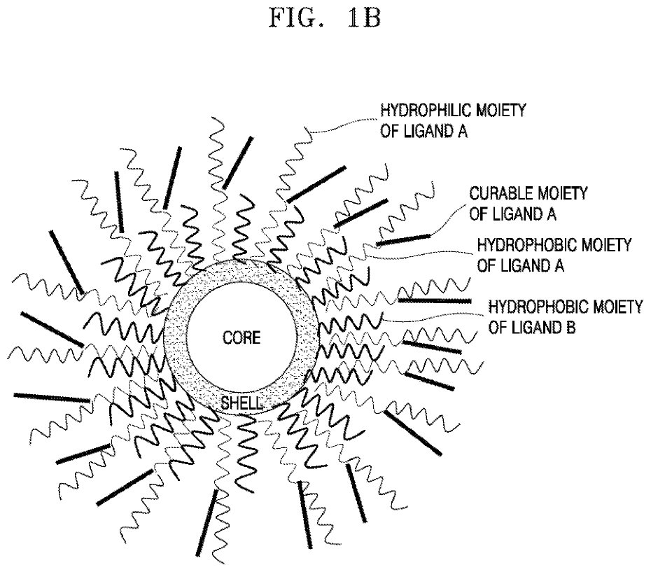

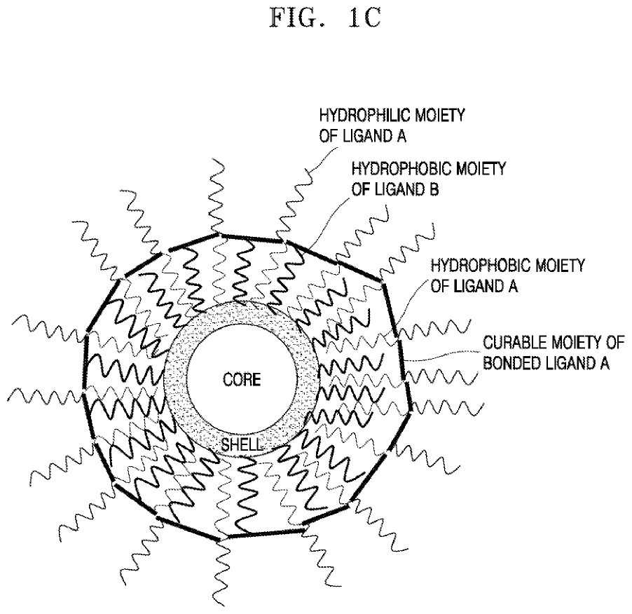

FIG. 1A is a schematic view of a structure of a quantum dot-containing complex coordinated with ligands B containing hydrophobic moieties. In the related art, a state in which only hydrophobic ligands are coordinated to the quantum dot before being made into ink is illustrated.

Embodiments provide a quantum dot-containing complex which may include: a quantum dot; and
ligands A and ligands B, wherein
the ligands B may be coordinated to a surface of the quantum dot,
each of the ligands A may include a hydrophilic moiety, a hydrophobic moiety, and a curable moiety, and
each of the ligands B may include a hydrophobic moiety.

The ligands A and the ligands B may each independently be at least two ligands.

In an embodiment, instead of being substituted with hydrophilic ligands, hydrophobic ligands B coordinated to the quantum dot as illustrated in FIG. 1A may be allowed to react with ligands A each containing a hydrophilic ligand, a hydrophobic ligand, and a curable moiety, to form a micelle and make the quantum dot into ink.

The expression “each of the ligands B includes a hydrophobic moiety” does not indicate that “each of the ligands B consists of a hydrophobic moiety.” This may mean “each of the ligands B does not include a hydrophilic moiety and/or a curable moiety.”

For example, the ligands B may each include an element (e.g., oxygen (O), sulfur (S), nitrogen (N), or a halogen) having a non-covalent electron pair capable of coordinating to the surface of the quantum dot. For example, the ligands B may each include a C₁-C₆₀ alkyl group, a C₂-C₆₀ alkenyl group, a C₂-C₆₀ alkynyl group, and/or a C₆-C₆₀ aryl group, including O, S, N, a halogen, or the like. For example, the ligand B may include a C₅-C₆₀ alkyl group, a C₅-C₆₀ alkenyl group, a C₅-C₆₀ alkynyl group, and/or a C₆-C₆₀ aryl group, including O, S, N, a halogen, or the like. For example, the ligands B may each include oleic acid, laurinic acid, stearic acid, palmitic acid, linoleic acid, linolenic acid, or the like.

In an embodiment, the hydrophobic moiety of the ligands A and the hydrophobic moiety of the ligands B may be bonded to each other via van der Waals forces.

FIG. 1B is a schematic view of a structure of a quantum dot-containing complex in which hydrophobic moieties of ligands A may be bonded to hydrophobic moieties of ligands B via van der Waals forces, such that the ligands A form a micelle around a quantum dot.

Instead of substitution of the ligands A with the ligands B, the hydrophobic moieties of the ligands A and the hydrophobic moieties of the ligands B may be bonded to each other via van der Waals forces, thereby surrounding the quantum dot.

A molar ratio of the ligand A to the ligand B may be in a range of about 1:9 to about 9:1. For example, the molar ratio of the ligand A to the ligand B may be in a range of about 4:5 to about 5:4.

In an embodiment, the hydrophobic moieties of the ligands A may face inward toward the quantum dot, and the hydrophilic moieties of the ligands A may face outward from the quantum dot, such that the ligands A may form a micelle.

Since the hydrophobic moieties of the ligands A and the hydrophobic moieties of the ligands B are not covalently bonded to each other, the ligands A may escape again from the quantum dot. The hydrophobic moiety of the ligands A may include, for example, a C₁-C₆₀ alkyl group, a C₂-C₆₀ alkenyl group, a C₂-C₆₀ alkynyl group, a C₆-C₆₀ aryl group, or any combination thereof. The hydrophobic moiety of the ligands A may include, for example, a C₅-C₆₀ alkyl group, a C₅-C₆₀ alkenyl group, a C₅-C₆₀ alkynyl group, a C₆-C₆₀ aryl group, or any combination thereof. For van der Waals forces to act, it may be necessary to include 5 or more carbon atoms.

FIG. 1C is a schematic view of a structure in which curable moieties of ligands A are bonded to each other to form a single molecule, thereby encapsulating a quantum dot.

The curable moiety of the ligands A may be, for example, a photocurable moiety or a thermosetting moiety. For example, in an embodiment, the curable moiety of the ligands A may be a thermosetting moiety.

As illustrated in FIG. 1C, the curable moieties of the ligands A may be bonded to each other, and thus, even though the hydrophobic moieties of the ligands A may not coordinate to the surface of the quantum dot, the ligands A do not readily escape from the quantum dot.

In embodiments, the curable moieties of the ligands A may be covalently bonded to each other, thereby forming a single molecule. The expression “form a single molecule” does not indicate that the curable moieties of the ligands A are bonded to each other, so that all of the ligands A are linked to each other to thereby form a single molecule. For example, among the ligands A surrounding the quantum dot, there may be some unreacted curable moieties of the ligands A.

The thermosetting moiety may not be limited as long as the thermosetting moiety undergoes a curing reaction by heat. For example, the thermosetting moiety may include an epoxy group.

In an embodiment, each ligand A may be a compound in which a hydrophilic moiety, a curable moiety, and a hydrophobic moiety are bonded in this order. The hydrophilic moiety, the curable moiety, and the hydrophobic moiety may each independently include a crosslinkable group, the crosslinkable groups being capable of bonding to each other.

For example, the hydrophilic moiety, the curable moiety, and the hydrophilic moiety may each independently include a (meth)acrylate group. For example, the (meth)acrylate group of the hydrophilic moiety, the (meth)acrylate group of the curable moiety, and the (meth)acrylate group of the hydrophobic moiety may be bonded to thereby form a compound (e.g., the ligand A) in which the hydrophilic moiety, the curable moiety, and the hydrophobic moiety are bonded in this order.

For example, the hydrophilic moiety, the hydrophobic moiety, and the curable moiety of the ligand A may be linked to one another via SP³ carbon bonds.

In an embodiment, the hydrophilic moiety, the curable moiety, and the hydrophobic moiety of the ligands A may each independently be 1 to 5 moieties. For example, each ligand A may be a compound in which the hydrophilic moiety, the curable moiety, and the hydrophobic moiety are bonded in this order. For example, each ligand A may be a compound in which a hydrophilic moiety 1, a hydrophilic moiety 2, a curable moiety, and a hydrophobic moiety are bonded in this order. For example, each ligand A may be a compound in which a hydrophilic moiety, a curable moiety 1, a curable moiety 2, and a hydrophobic moiety are bonded in this order. For example, each ligand A may be a compound in which a hydrophilic moiety, a curable moiety 1, a curable moiety 2, a hydrophobic moiety 1, and a hydrophobic moiety 2 are bonded in this order.

In an embodiment, the hydrophilic moiety 1 and the hydrophilic moiety 2 may be identical to or different from each other, and may be linked via bonding of crosslinkable groups capable of bonding to each other. The crosslinkable group may be, for example, a (meth)acrylate group.

In an embodiment, the hydrophobic moiety 1 and the hydrophobic moiety 2 may be identical to or different from each other, and may be linked via bonding of crosslinkable groups capable of bonding to each other.

In an embodiment, the crosslinkable moiety 1 and the crosslinkable moiety 2 may be identical to or different from each other, and may be linked via bonding of crosslinkable groups capable of bonding to each other.

The hydrophilic moiety of the ligands A may be any moiety with hydrophilicity. For example, the hydrophilic moiety may include a carboxyl group, a hydroxyl group, an amine group, ethylene glycol, or the like.

In an embodiment, the hydrophobic moieties of the ligands A may not be coordinated to the surface of the quantum dot.

In an embodiment, the hydrophobic moiety of each ligand B may have a length equal to or less than a length of the hydrophobic moiety of each ligand A. When the length of the hydrophobic moiety of the ligand B is greater than the length of the hydrophobic moiety of the ligand A, bonding between the curable moieties of the ligands A may not be readily performed.

In an embodiment, the ligands A may include a compound represented by one of Formulae 1 to 3:

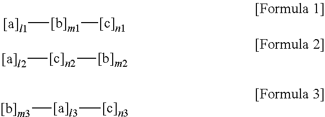

In Formulae 1 to 3,
a may be a group represented by Formula 1-1 or Formula 1-2,

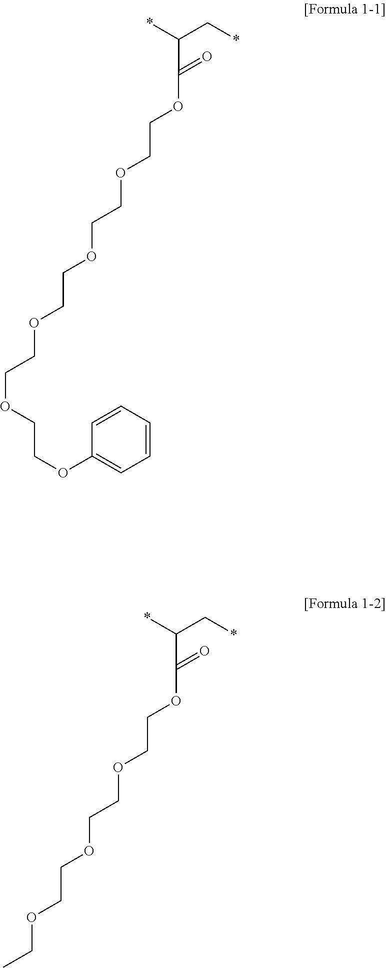 [SMILES: *CC(*)C(=O)OCCOCCOCCOCCOCCOc1ccccc1 ; *CC(*)C(=O)OCCOCCOCCOCC]

b may be a group represented by Formula 2-1,

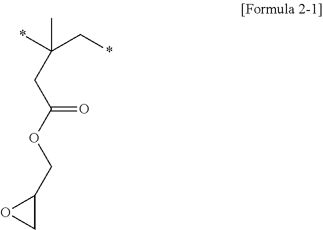 [SMILES: *CC(*)(C)CC(=O)OCC1CO1]

c may be a group represented by Formula 3-1, Formula 3-2, or Formula 3-3,

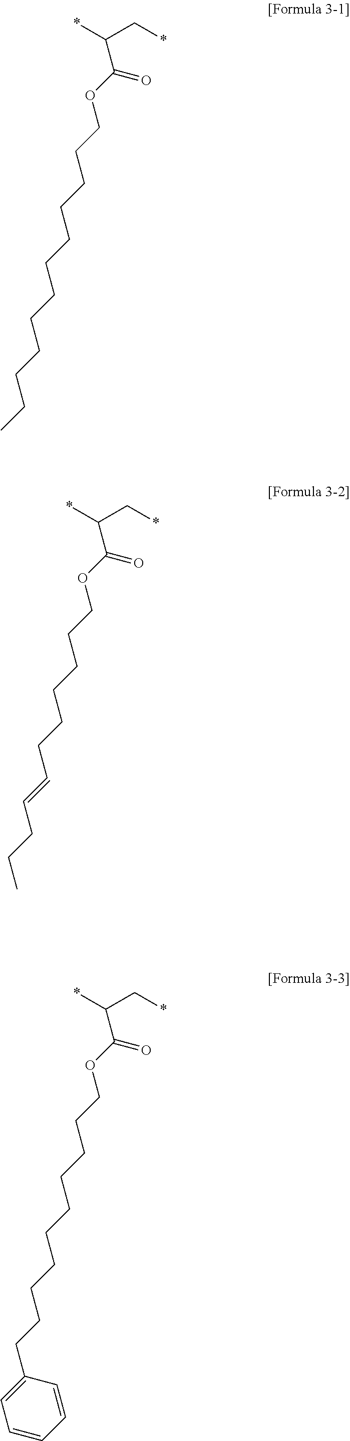 [SMILES: *CC(*)C(=O)OCCCCCCCCCCCC ; *CC(*)C(=O)OCCCCCC/C=C/CCC ; *CC(*)C(=O)OCCCCCCCCCCc1ccccc1]

I1 to I3, m1 to m3, and n1 to n3 may each independently be an integer from 1 to 5,
when I1 is 2 or more, two or more of a in Formula 1 may be identical to or different from each other,
when I2 is 2 or more, two or more of a in Formula 2 may be identical to or different from each other,
when I3 is 2 or more, two or more of a in Formula 3 may be identical to or different from each other,
when n1 is 2 or more, two or more of c in Formula 1 may be identical to or different from each other,
when n2 is 2 or more, two or more of c in Formula 2 may be identical to or different from each other,
when n3 is 2 or more, two or more of c in Formula 3 may be identical to or different from each other, and
in Formulae 1-1, 1-2, 2-1, and 3-1 to 3-3, * denotes a bond, except that * at an end of a molecule denotes hydrogen.

For example, the ligands A may include any one of Ligands 1 to 4.

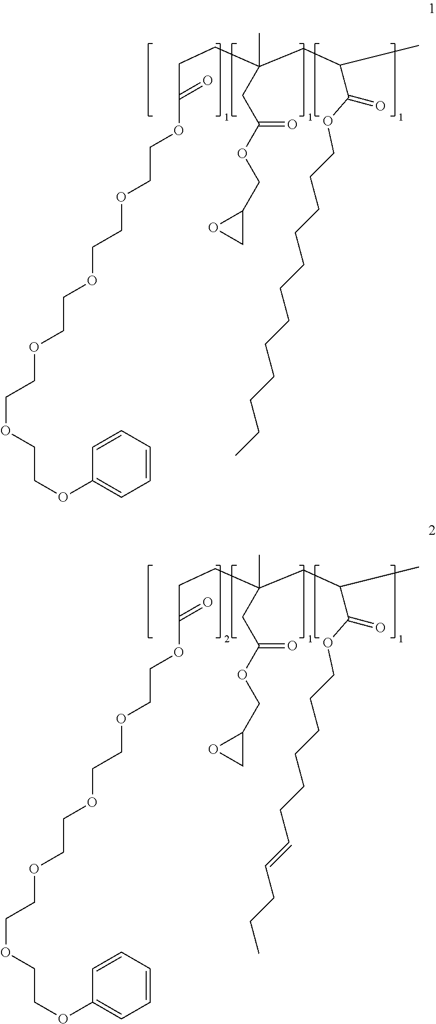

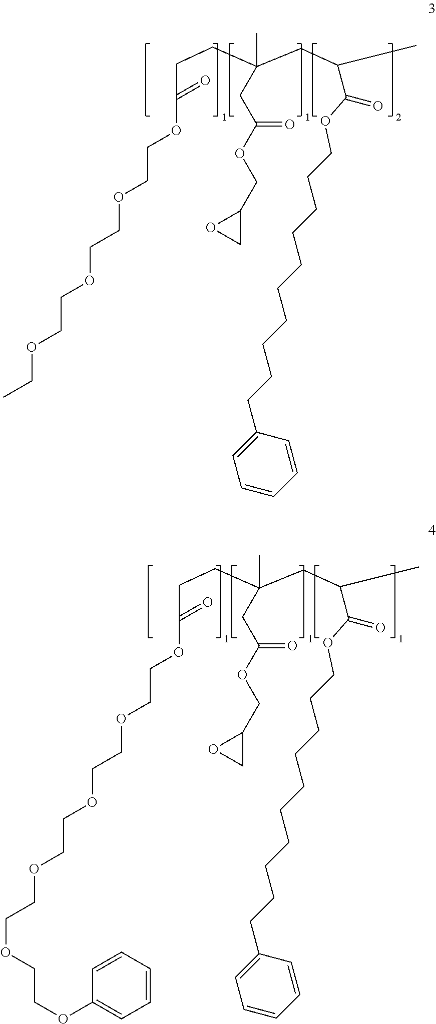

The quantum dot will be described below.

According to embodiments, a quantum dot composition may include the quantum dot-containing complex.

In an embodiment, the composition may further include a crosslinkable monomer, an initiator, and the like.

A weight ratio of the quantum dot-containing complex to the monomer may be in a range of about 1:0.5 to about 1:2.

In an embodiment, the initiator may include diphenyl(2,4,6-trimethylbenzoyl)phosphine oxide, 4-acryloxybenzophenone, 2,2-dimethoxy-2-phenylacetophenone, 2-hydroxy-2-methyl-1-phenyl-1-propan-1-one, ethyl(2,4,6-trimethylbenzoyl)phenyl phosphinate, bisacylphosphine oxide, or any combination thereof.

In an embodiment, the crosslinkable monomer may be an acrylic monomer.

For example, the crosslinkable monomer may include 1,6-hexanediol diacrylate, 2-ethylhexyl (meth)acrylate, ethyl (meth)acrylate, methyl (meth)acrylate, n-propyl (meth)acrylate, isopropyl (meth)acrylate, pentyl (meth)acrylate, n-octyl (meth)acrylate, isooctyl (meth)acrylate, isononyl (meth)acrylate, n-butyl (meth)acrylate, isobutyl (meth)acrylate, n-hexyl (meth)acrylate, n-nonyl (meth) acrylate, isoamyl (meth)acrylate, n-decyl (meth) acrylate, isodecyl (meth)acrylate, dodecyl (meth)acrylate, isobornyl (meth)acrylate, cyclohexyl (meth)acrylate, phenyl (meth)acrylate, benzyl (meth)acrylate, isostearyl (meth)acrylate, 2-methylbutyl (meth)acrylate, or any combination thereof.

In an embodiment, the composition may have a viscosity (at 25° C.) in a range of about 2 cP to about 30 cP.

When the viscosity is within the above range, there may be no difficulty in forming a layer using the composition according to an embodiment by a solution process, e.g., spin coating or inkjet printing.

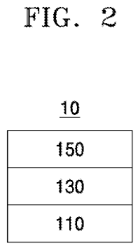

### Description of FIG. 2

FIG. 2 is a schematic cross-sectional view of a light-emitting device 10 according to an embodiment. The light-emitting device 10 includes a first electrode 110, an interlayer 130, and a second electrode 150.

Hereinafter, the structure of the light-emitting device 10 according to an embodiment and a method of manufacturing the light-emitting device 10 will be described with reference to FIG. 2.

### [First Electrode 110]

In FIG. 2, a substrate may be further included under the first electrode 110 or above the second electrode 150. In an embodiment, the substrate may be a glass substrate or a plastic substrate. In embodiments, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates the injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. For example, the first electrode 110 may have a three-layered structure of ITO/Ag/ITO.

### [Interlayer 130]

The interlayer 130 may be disposed on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include, in addition to various organic materials, a metal-containing compound such as an organometallic compound, an inorganic material such as quantum dots, or the like.

In an embodiment, the interlayer 130 may include two or more emitting units stacked between the first electrode 110 and the second electrode 150, and at least one charge generation layer between the two or more emitting units. When the interlayer 130 includes the two or more emitting units and the at least one charge generation layer, the light-emitting device 10 may be a tandem light-emitting device.

### [Hole Transport Region in Interlayer 130]

The hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron blocking layer, or any combination thereof.

For example, the hole transport region may have a multi-layered structure of hole injection layer/hole transport layer, hole injection layer/hole transport layer/emission auxiliary layer, hole injection layer/emission auxiliary layer, hole transport layer/emission auxiliary layer, or hole injection layer/hole transport layer/electron blocking layer, wherein the layers of each structure may be stacked from the first electrode 110 in its respective stated order, but the structure of the hole transport region is not limited thereto.

The hole transport region may include a compound represented by Formula 201, a compound represented by Formula 202, or any combination thereof:

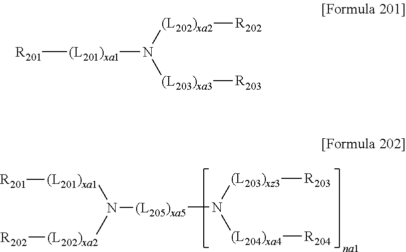

In Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—*′, *—S—*′, *—N(Q₂₀₁)—*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R₂₀₁ and R₂₀₂ may optionally be bonded to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group (for example, a carbazole group) that is unsubstituted or substituted with at least one R₁₀ₐ (for example, Compound HT16 below),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group that is unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulae CY201 to CY217:

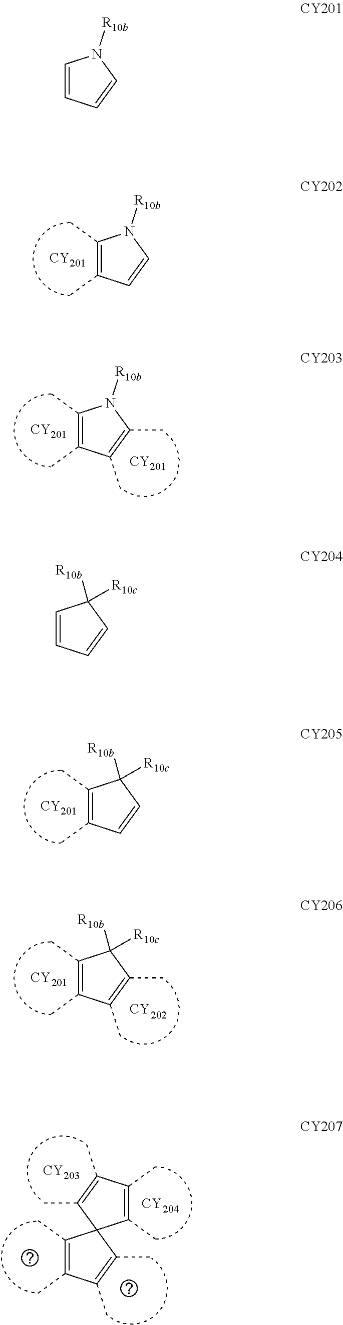

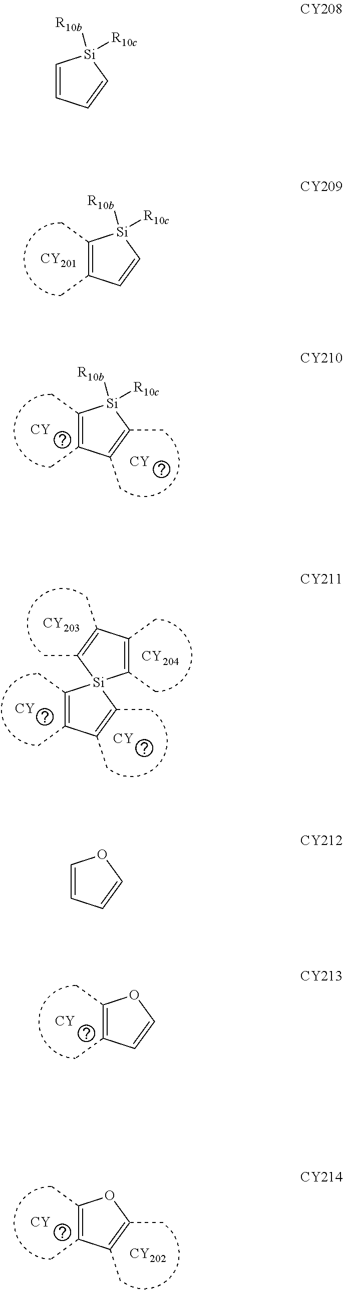

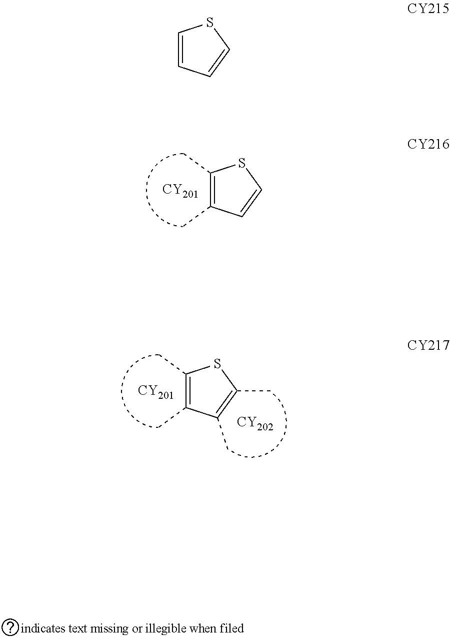

In Formulae CY201 to CY217, R_{10b} and R_{10c} may each independently be the same as defined herein with regard to R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

In an embodiment, ring CY₂₀₁ to ring CY₂₀₄ in Formulae CY201 to CY217 may each independently be a benzene group, a naphthalene group, a phenanthrene group, or an anthracene group.

In embodiments, the compound represented by Formula 201 and the compound represented by Formula 202 may include at least one of groups represented by Formulae CY201 to CY203.

In embodiments, the compound represented by Formula 201 may include at least one of the groups represented by Formulae CY201 to CY203 and at least one of the groups represented by Formulae CY204 to CY217.

In embodiments, in Formula 201, xa1 may be 1, R₂₀₁ may be one of groups represented by Formulae CY201 to CY203, xa2 may be 0, and R₂₀₂ may be one of the groups represented by Formulae CY204 to CY207.

In embodiments, the compound represented by Formula 201 and the compound represented by Formula 202 may each not include groups represented by Formulae CY201 to CY203.

In embodiments, the compound represented by Formula 201 and the compound represented by Formula 202 may each not include groups represented by Formulae CY201 to CY203, and may each independently include at least one of groups represented by Formulae CY204 to CY217.

In embodiments, the compound represented by Formula 201 and the compound represented by Formula 202 may each not include the groups represented by Formulae CY201 to CY217.

For example, the hole transport region may include one of Compounds HT1 to HT46, m-MTDATA, TDATA, 2-TNATA, NPB(NPD), B-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

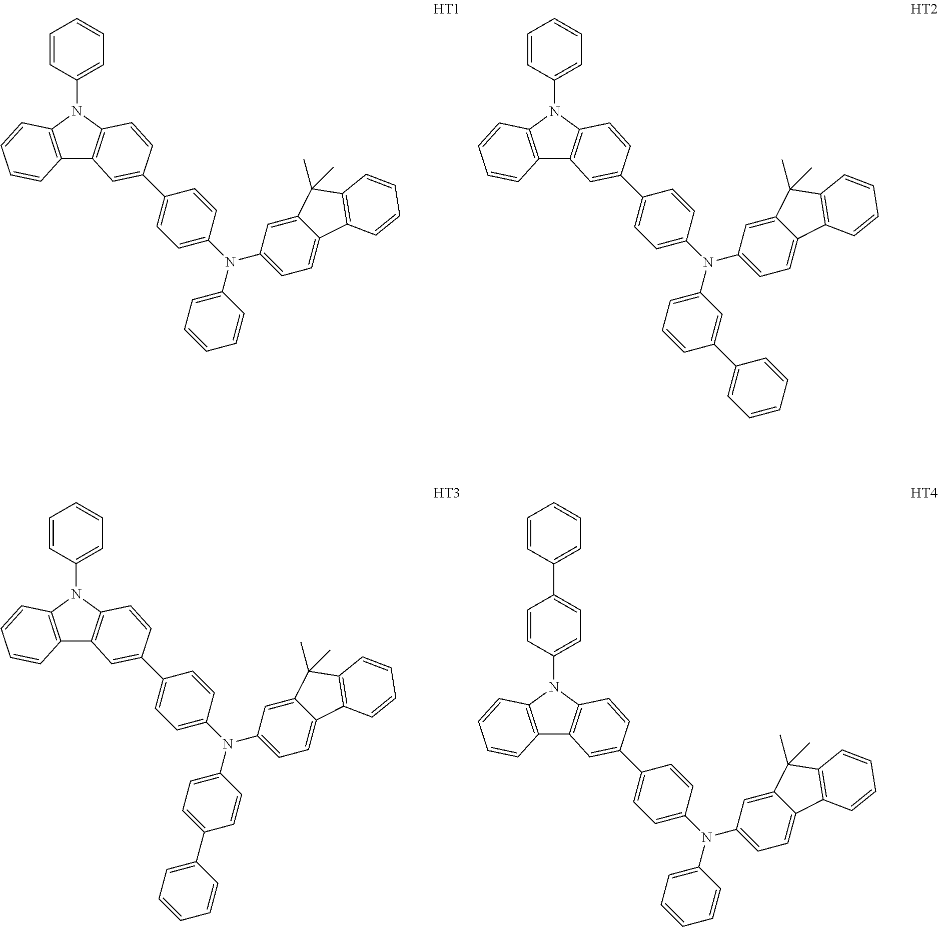 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

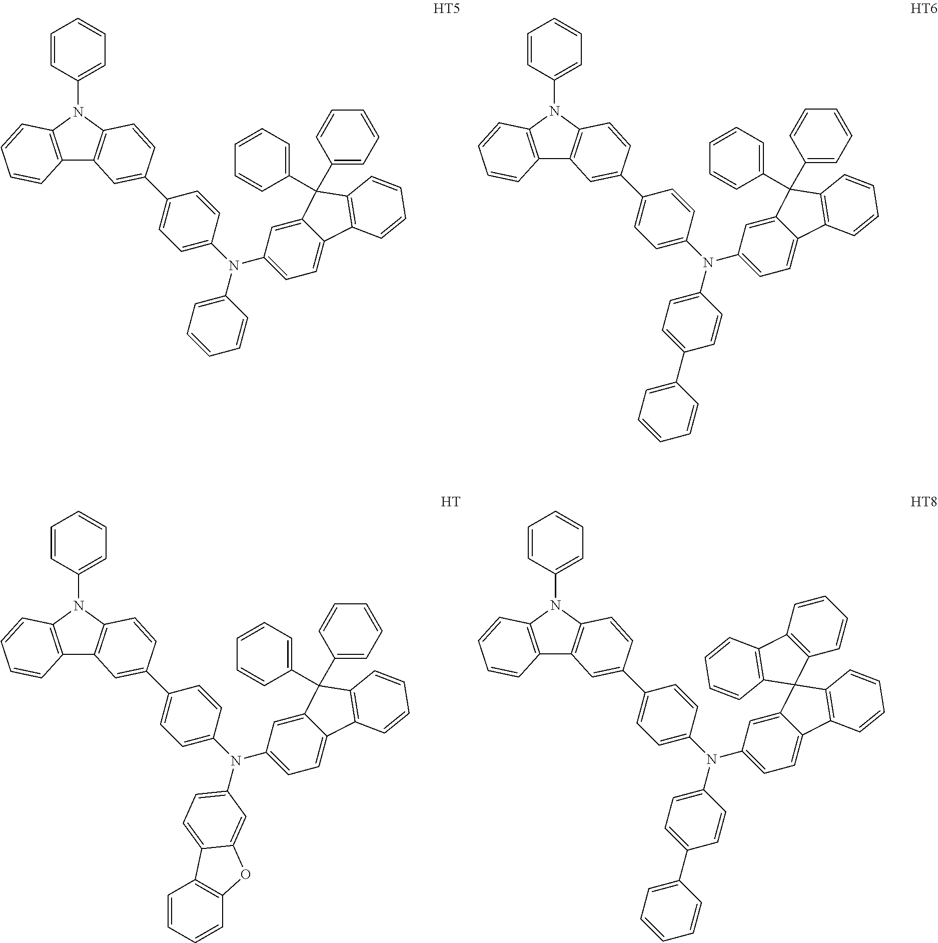 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

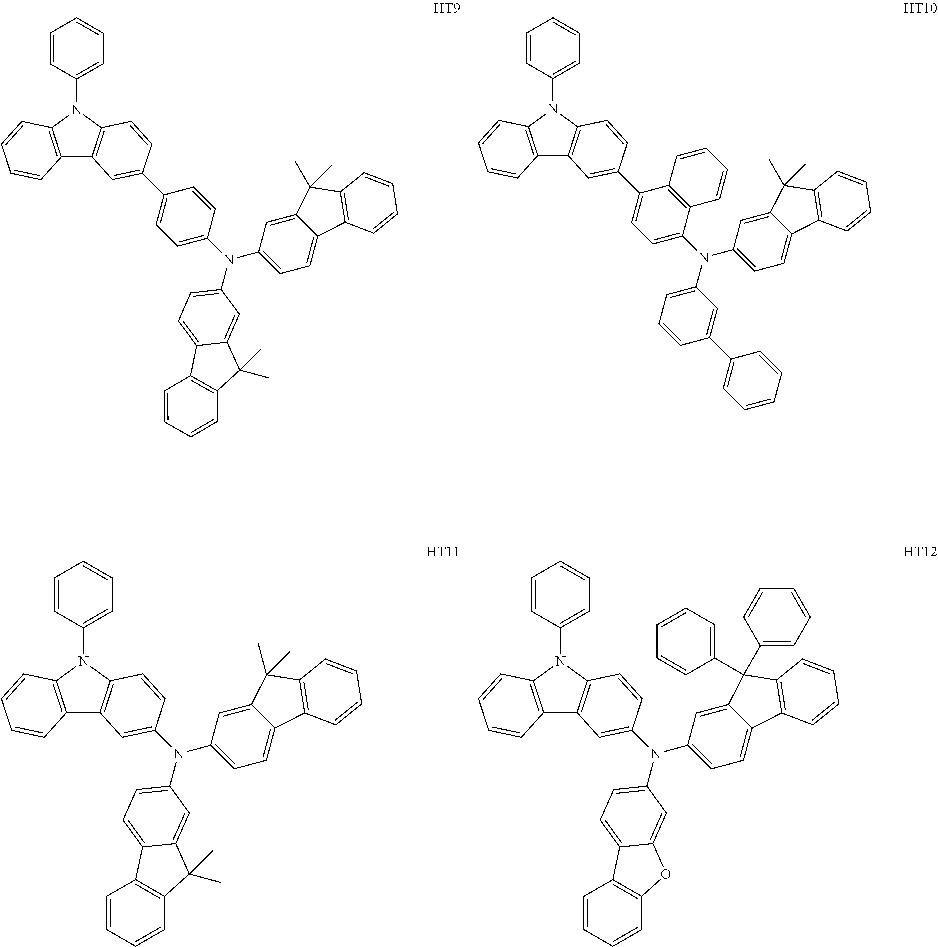 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

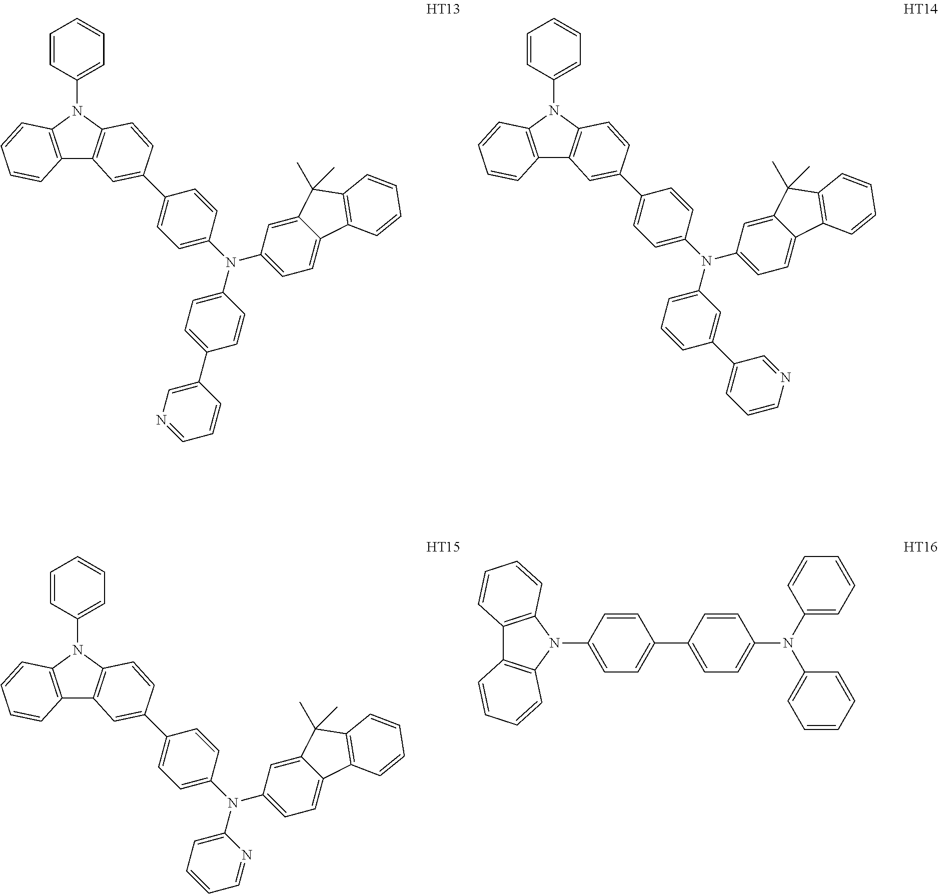 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

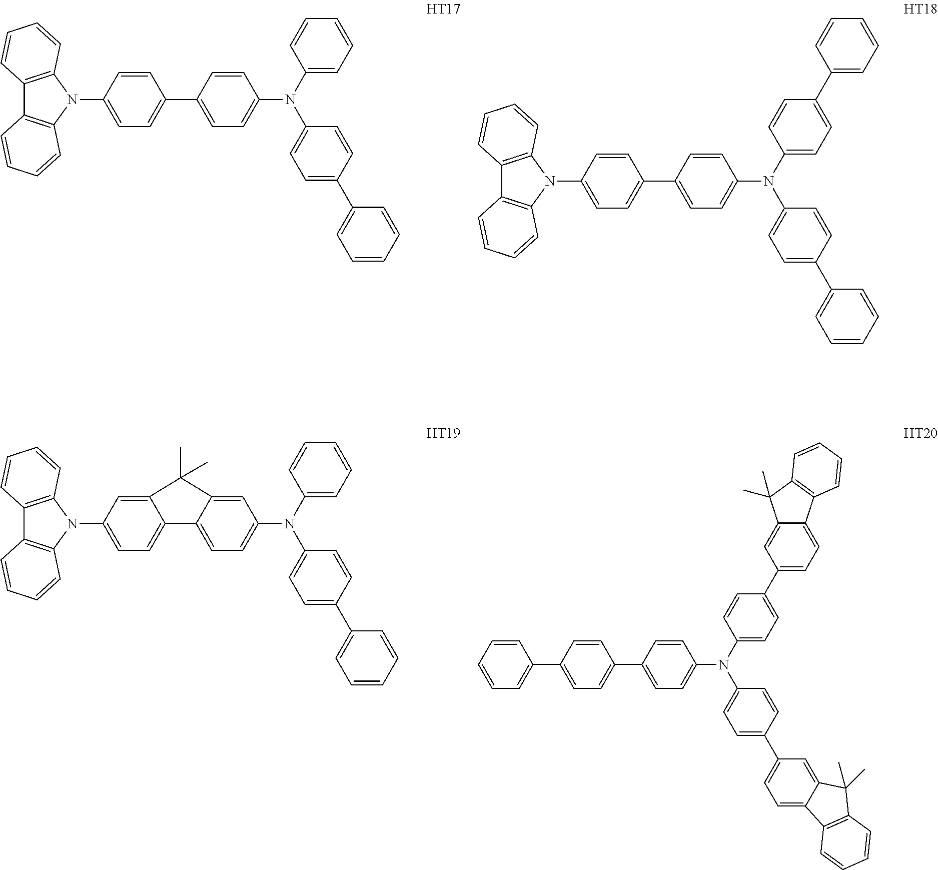 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

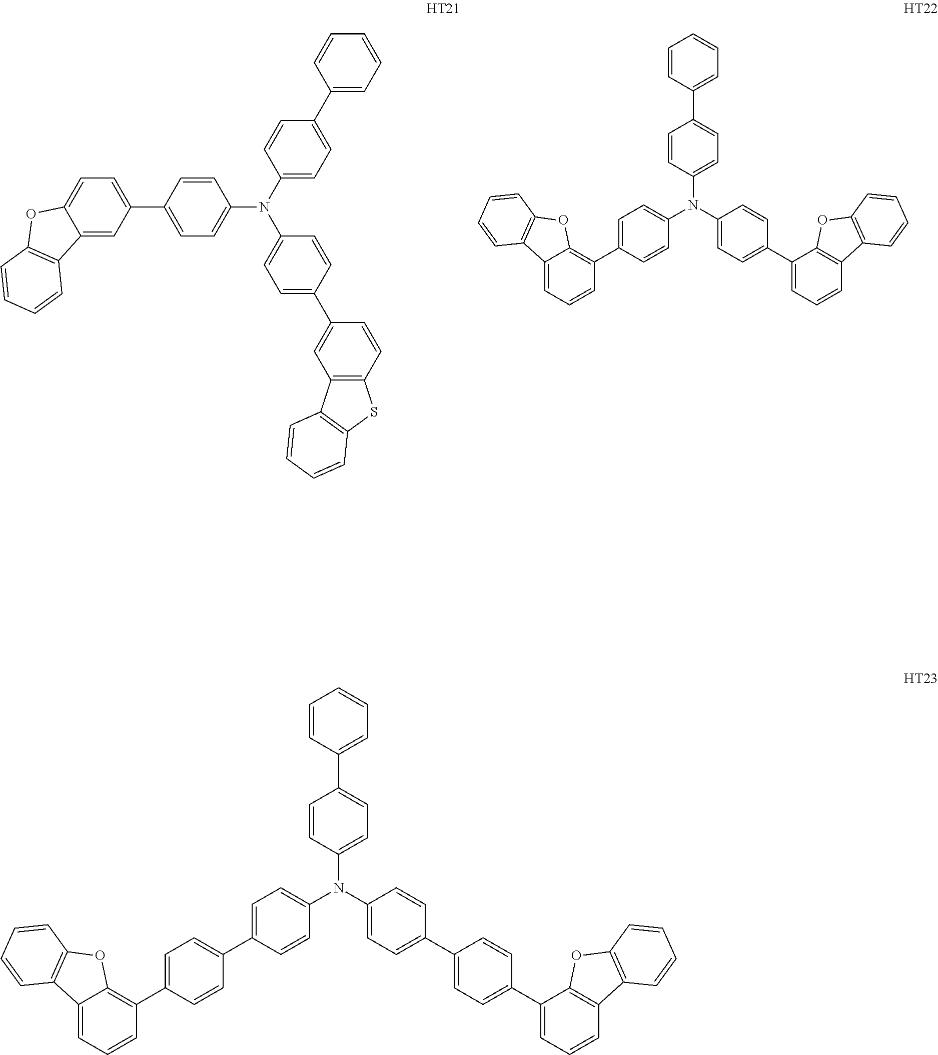 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

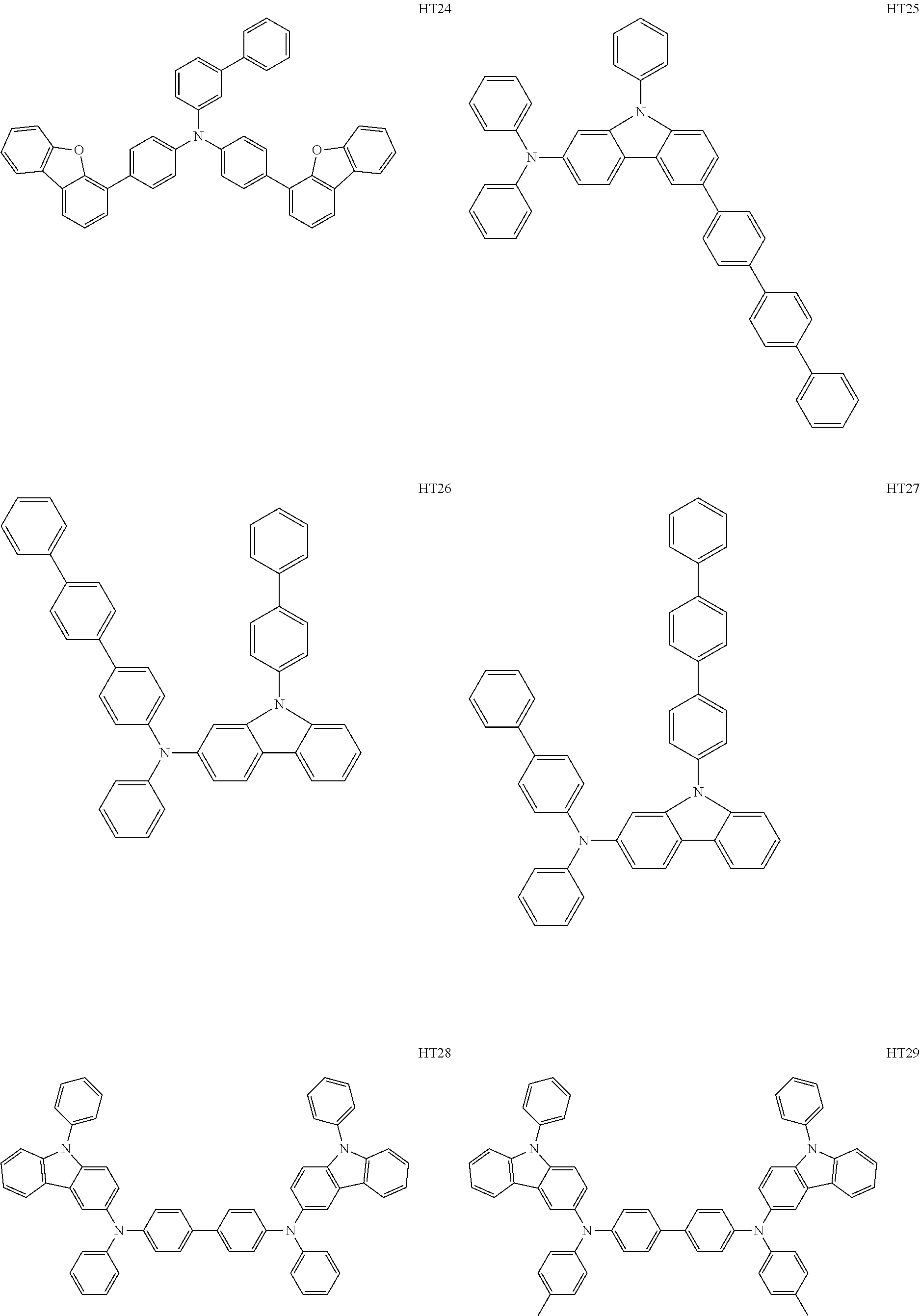

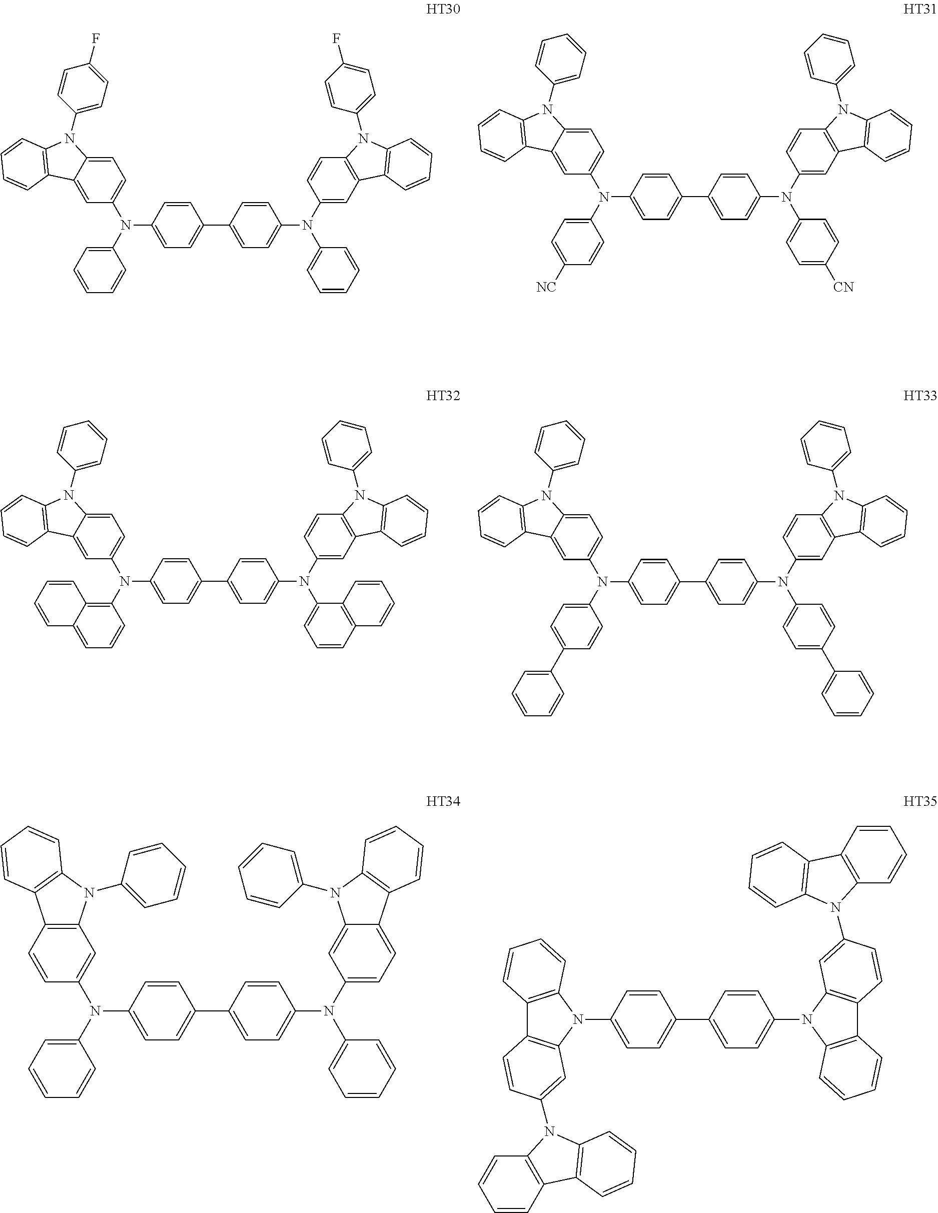

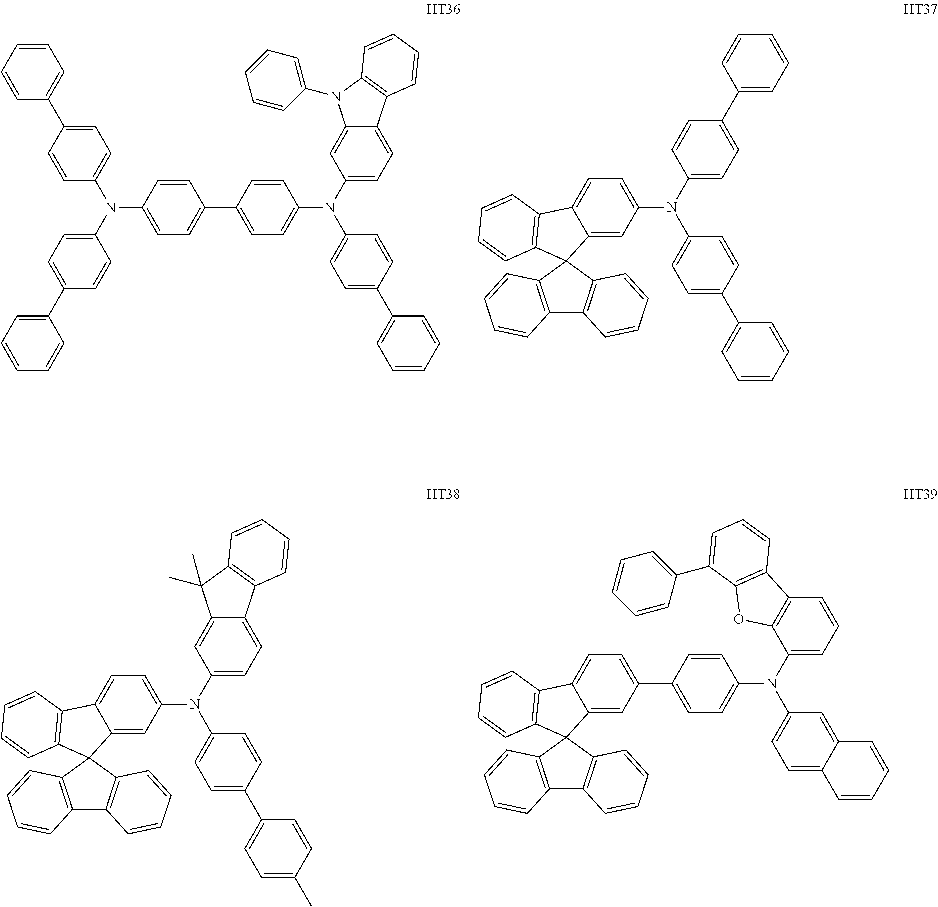 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

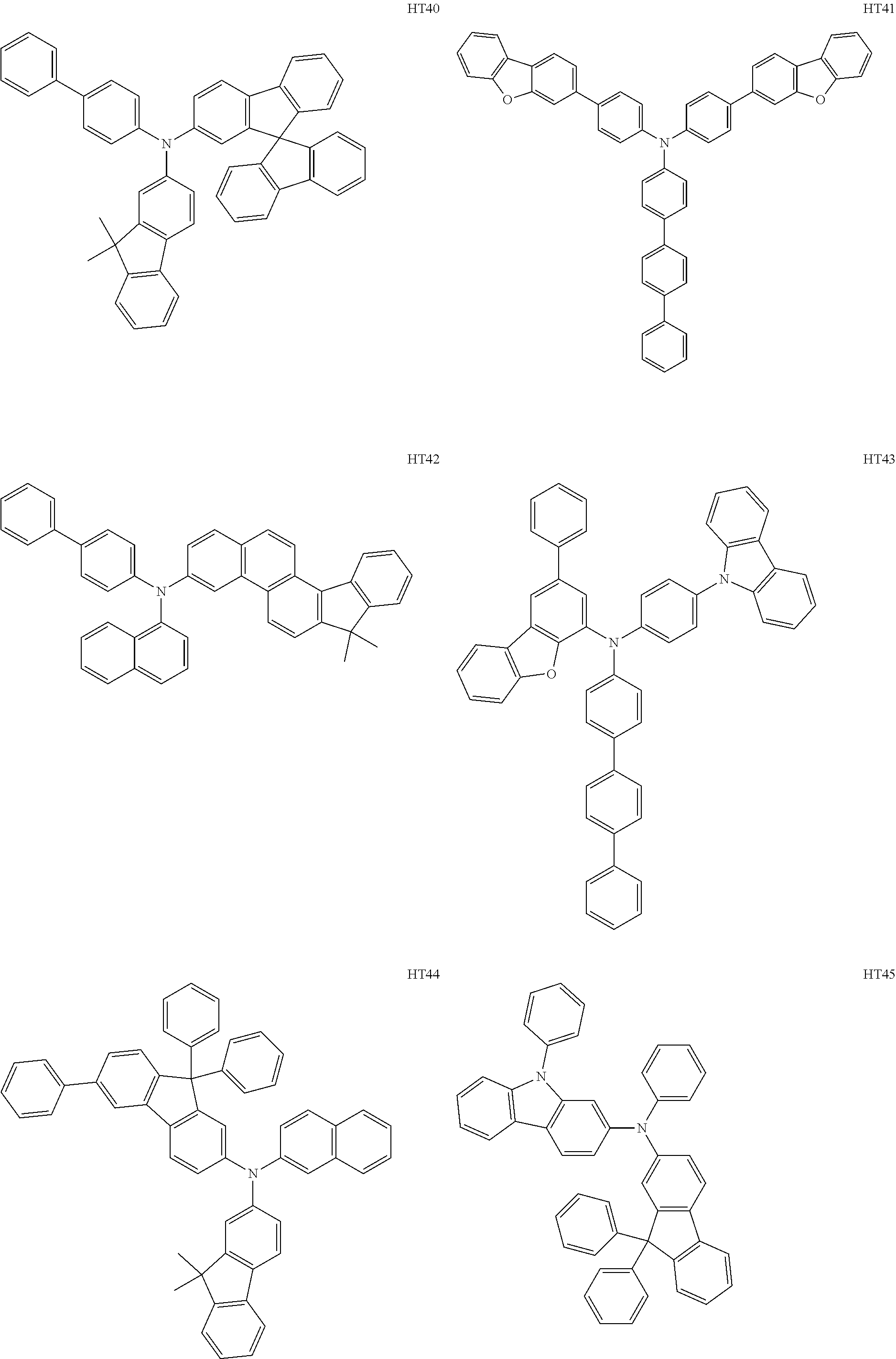

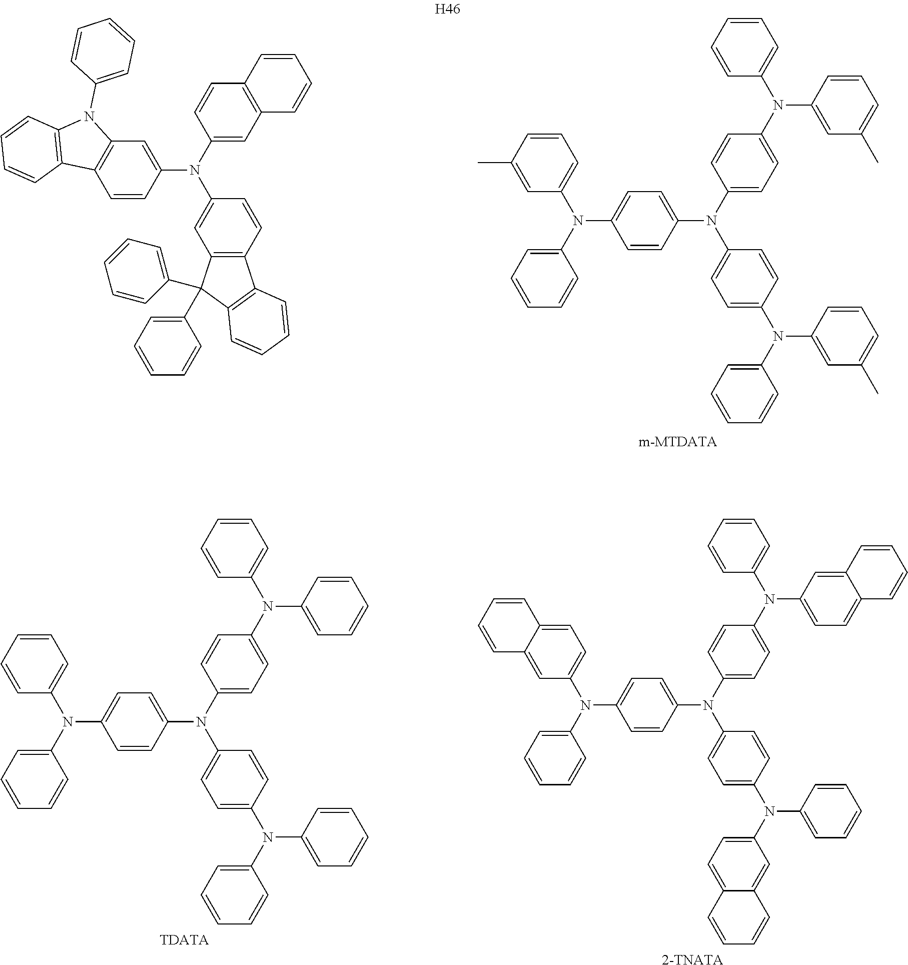

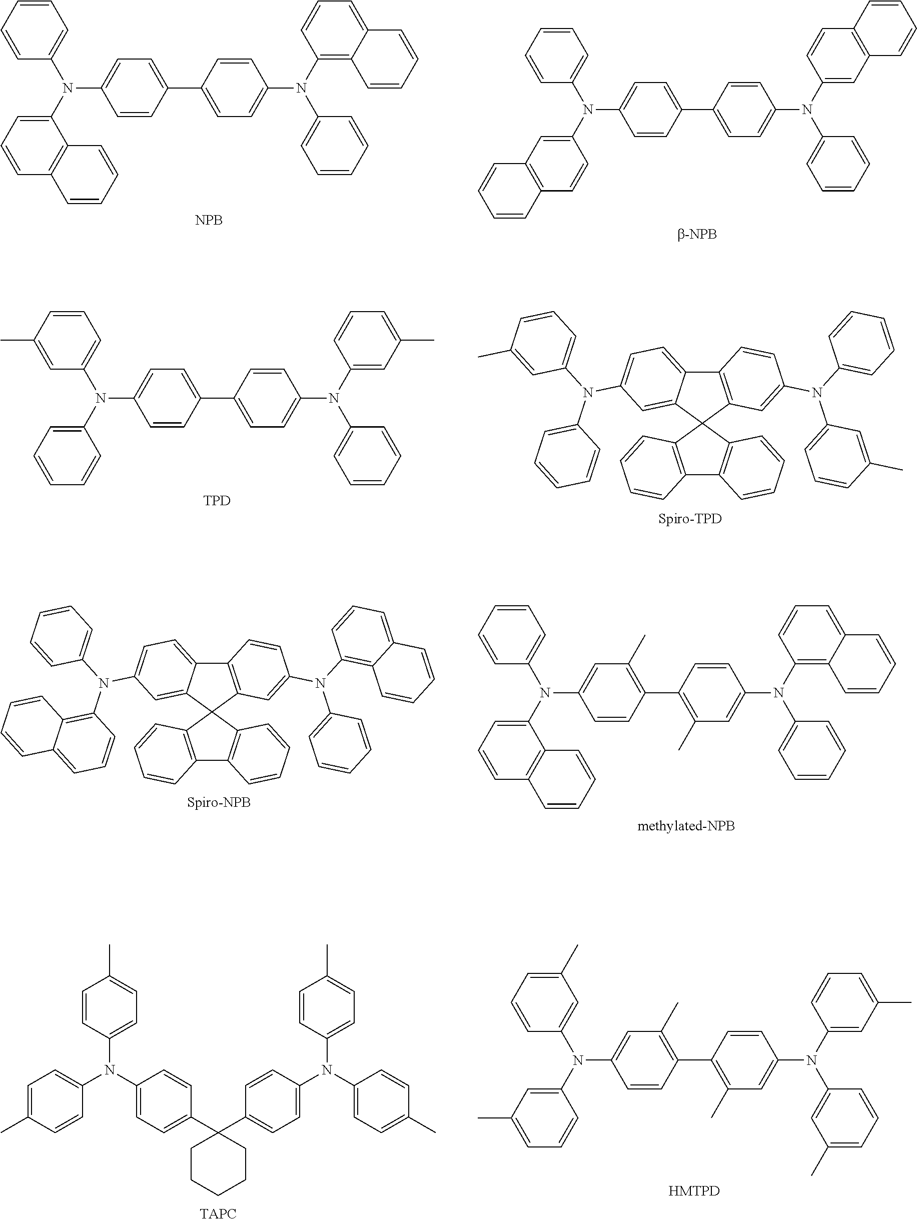

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection region may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to a wavelength of light emitted from the emission layer, and the electron blocking layer may block the leakage of electrons from the emission layer to the hole transport region. Materials that may be included in the hole transport region may be included in the emission auxiliary layer and the electron blocking layer.

[p-Dopant]

The hole transport region may further include, in addition to the materials as described above, a charge-generating material for conductivity enhancement. The charge-generating material may be uniformly or non-uniformly dispersed in the hole transport region (for example, in the form of a single layer consisting of a charge-generating material).

The charge-generating material may be, for example, a p-dopant.

For example, the p-dopant may have a lowest unoccupied molecular orbital (LUMO) energy level less than or equal to about −3.5 eV.

In an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

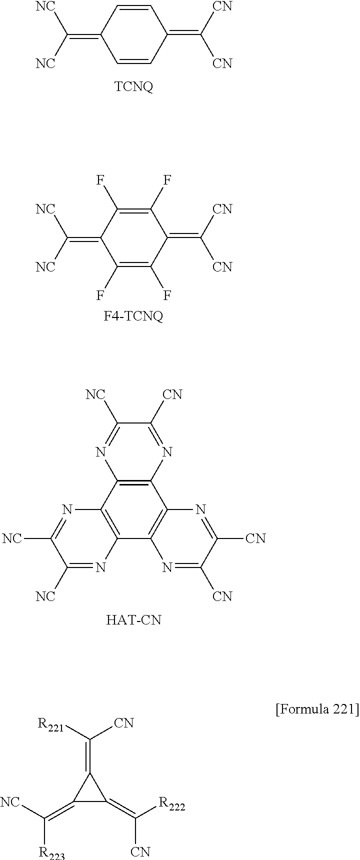

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each of which is substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include an alkali metal (e.g., lithium (Li), sodium (Na), potassium (K), rubidium (Rb), or cesium (Cs)); an alkaline earth metal (e.g., beryllium (Be), magnesium (Mg), calcium (Ca), strontium (Sr), or barium (Ba)); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), or gold (Au)); a post-transition metal (e.g., zinc (Zn), indium (In), or tin (Sn)); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu)); and the like.

Examples of a metalloid may include silicon (Si), antimony (Sb), tellurium (Te), and the like.

Examples of a non-metal may include oxygen (O), a halogen (e.g., F, Cl, Br, or I), and the like.

Examples of the compound including element EL1 and element EL2 may include a metal oxide, a metal halide (e.g., a metal fluoride, a metal chloride, a metal bromide, or a metal iodide), a metalloid halide (e.g., a metalloid fluoride, a metalloid chloride, a metalloid bromide, or a metalloid iodide), a metal telluride, or any combination thereof.

Examples of a metal oxide may include a tungsten oxide (e.g., WO, W₂O₃, WO₂, WO₃, or W₂O₅), a vanadium oxide (e.g., VO, V₂O₃, VO₂, or V₂O₅), a molybdenum oxide (e.g., MoO, Mo₂O₃, MoO₂, MoO₃, or Mo₂O₅), a rhenium oxide (e.g., ReO₃), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and the like.

Examples of a transition metal halide may include a titanium halide (e.g., TiF₄, TiCl₄, TiBr₄, or TiI₄), a zirconium halide (e.g., ZrF₄, ZrCl₄, ZrBr₄, or ZrI₄), a hafnium halide (e.g., HfF₄, HfCl₄, HfBr₄, or HfI₄), a vanadium halide (e.g., VF₃, VCl₃, VBr₃, or VI₃), a niobium halide (e.g., NbF₃, NbCl₃, NbBr₃, or NbI₃), a tantalum halide (e.g., TaF₃, TaCl₃, TaBr₃, or TaI₃), a chromium halide (e.g., CrF₃, CrCl₃, CrBr₃, or CrI₃), a molybdenum halide (e.g., MoF₃, MoCl₃, MoBr₃, or MoI₃), a tungsten halide (e.g., WF₃, WCl₃, WBr₃, or WI₃), a manganese halide (e.g., MnF₂, MnCl₂, MnBr₂, or MnI₂), a technetium halide (e.g., TcF₂, TcCl₂, TcBr₂, or TcI₂), a rhenium halide (e.g., ReF₂, ReCl₂, ReBr₂, or ReI₂), an iron halide (e.g., FeF₂, FeCl₂, FeBr₂, or FeI₂), a ruthenium halide (e.g., RuF₂, RuCl₂, RuBr₂, or RuI₂), an osmium halide (e.g., OsF₂, OsCl₂, OsBr₂, or OsI₂), a cobalt halide (e.g., CoF₂, CoCl₂, CoBr₂, or Col₂), a rhodium halide (e.g., RhF₂, RhCl₂, RhBr₂, or RhI₂), an iridium halide (e.g., IrF₂, IrCl₂, IrBr₂, or IrI₂), a nickel halide (e.g., NiF₂, NiCl₂, NiBr₂, or NiI₂), a palladium halide (e.g., PdF₂, PdCl₂, PdBr₂, or PdI₂), a platinum halide (e.g., PtF₂, PtCl₂, PtBr₂, or PtI₂), a copper halide (e.g., CuF, CuCl, CuBr, or CuI), a silver halide (e.g., AgF, AgCl, AgBr, or AgI), a gold halide (e.g., AuF, AuCl, AuBr, or AuI), and the like.

Examples of a post-transition metal halide may include a zinc halide (e.g., ZnF₂, ZnCl₂, ZnBr₂, or ZnI₂), an indium halide (e.g., InI₃), a tin halide (e.g., SnI₂), and the like.

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of a metalloid halide may include an antimony halide (e.g., SbCl₅) and the like.

Examples of a metal telluride may include an alkali metal telluride (e.g., Li₂Te, Na₂Te, K₂Te, Rb₂Te, or Cs₂Te), an alkaline earth metal telluride (e.g., BeTe, MgTe, CaTe, SrTe, or BaTe), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, or Au₂Te), a post-transition metal telluride (e.g., ZnTe), a lanthanide metal telluride (e.g., LaTe, CeTe, PrTe, NdTe, PmTe, EuTe, GdTe, TbTe, DyTe, HoTe, ErTe, TmTe, YbTe, or LuTe), and the like.

### [Emission Layer in Interlayer 130]

When the light-emitting device 10 is a full-color light-emitting device, the emission layer may be patterned into a red emission layer, a green emission layer, and/or a blue emission layer, according to a subpixel. In embodiments, the emission layer may have a stacked structure including two or more layers selected from a red emission layer, a green emission layer, and a blue emission layer, in which the two or more layers may contact each other or may be separated from each other, or may have a structure in which at least two of a red light-emitting material, a green light-emitting material, and a blue light-emitting material are mixed without layer separation, and may emit white light.

The emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight, with respect to 100 parts by weight of the host.

In another embodiment, the emission layer may include the quantum dot-containing complex as described above (hereinafter, also referred to as “quantum dot”).

In embodiments, the emission layer may include a delayed fluorescence material. The delayed fluorescence material may serve as a host or a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within these ranges, excellent luminescence characteristics may be obtained without a substantial increase in driving voltage.

### [Quantum Dot]

The emission layer may include a quantum dot.

In the specification, a “quantum dot” may be a crystal of a semiconductor compound, and may include any material capable of emitting light of various emission wavelengths according to a size of the crystal. With the adjustment of an atomic ratio in the quantum dot compound, quantum dots may also emit light of various emission wavelengths.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any similar process.

The wet chemical process is a method in which a quantum dot particle crystal is grown after a precursor material is mixed with an organic solvent. When the crystal grows, the organic solvent naturally acts as a dispersant coordinated on the surface of the quantum dot crystal and controls the growth of the crystal. Thus, the wet chemical method may be more readily performed than a vapor deposition process such as metal organic chemical vapor deposition (MOCVD) or molecular beam epitaxy (MBE), and the growth of quantum dot particles may be controlled through an inexpensive process.

The quantum dot may include a Group II-VI semiconductor compound, a Group III-V semiconductor compound, a Group III-VI semiconductor compound, a Group I—III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

Examples of a Group III-V semiconductor compound may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAs, or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or any combination thereof. In an embodiment, a Group III-V semiconductor compound may further include a Group II element. Examples of a Group III-V semiconductor compound further including a Group II element may include InZnP, InGaZnP, InAlZnP, and the like.

Examples of a Group III-VI semiconductor compound may include: a binary compound, such as GaS, GaSe, GazSe₃, GaTe, InS, InSe, In₂S₃, In₂Se₃, or InTe; a ternary compound, such as InGaSs or InGaSes; or any combination thereof.

Examples of a Group I-III-VI semiconductor compound may include a ternary compound, such as AgInS, AgInS₂, CuInS, CuInS₂, CuGaO₂, AgGaO₂, or AgAlO₂; or any combination thereof such as AgInGaS or AgInGaS₂.

Examples of a Group IV-VI semiconductor compound may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or any combination thereof.

Examples of a Group IV element or compound may include: a single element material, such as Si or Ge; a binary compound, such as SiC or SiGe; or any combination thereof.

Each element included in a multi-element compound, such as a binary compound, a ternary compound, or a quaternary compound, may be present at a uniform concentration or at a non-uniform concentration in a particle.

In an embodiment, the quantum dot may have a single structure in which the concentration of each element in the quantum dot is uniform, or the quantum dot may have a core-shell structure. For example, a material included in the core and a material included in the shell may be different from each other.

The shell of the quantum dot may serve as a protective layer that prevents chemical degeneration of the core to maintain semiconductor characteristics, and/or may serve as a charging layer that imparts electrophoretic characteristics to the quantum dot. The shell may be a monolayer or a multilayer. An interface between the core and the shell may have a concentration gradient in which the concentration of a material present in the shell decreases toward the core.

Examples of a material forming the shell of the quantum dot may include an oxide material, a semiconductor compound, or any combination thereof. An oxide material may include a metal oxide, a metalloid oxide, a non-metal oxide, or any combination thereof. Examples of the oxide material (for example, a metal oxide, a metalloid oxide, and/or a non-metal oxide) may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, or CoMn₂O₄; or any combination thereof.

As described herein, examples of a semiconductor compound may include: a Group II-VI semiconductor compound; a Group III-V semiconductor compound; a Group III-VI semiconductor compound; a Group I—III-VI semiconductor compound; a Group IV-VI semiconductor compound; or any combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dot may have a full width at half maximum (FWHM) of an emission wavelength spectrum less than or equal to about 45 nm. For example, a FWHM of an emission wavelength spectrum of the quantum dot may be less than or equal to about 40 nm. For example, a FWHM of an emission wavelength spectrum of the quantum dot may be less than or equal to about 30 nm. When the FWHM of the quantum dot is within any of these ranges, color purity or color reproducibility may be improved. Light emitted through the quantum dot may be emitted in all directions, so that an optical viewing angle may be improved.

The quantum dot may be, for example, in a spherical form, a pyramidal form, a multi-arm form, or a cubic form, or the quantum dot may be in the shape of nanoparticles, nanotubes, nanowires, nanofibers, or nanoplate particles.

By adjusting the size of the quantum dot, the energy band gap may be adjusted, thereby obtaining light of various wavelengths in the quantum dot emission layer. Accordingly, by using quantum dots of different sizes, a light-emitting device that emits light of various wavelengths may be realized. In embodiments, the size of the quantum dot may be selected such that the quantum dot may emit red light, green light, and/or blue light. The size of the quantum dot may be configured such that the quantum dot may emit white light by combination of light of various colors.

### [Electron Transport Region in Interlayer 130]

The electron transport region may have a structure consisting of a layer consisting of a single material, a structure consisting of a layer including different materials, or a structure including multiple layers including different materials.

The electron transport region may include a hole blocking layer, an electron transport layer, an electron injection layer, or any combination thereof.

For example, the electron transport region may include an electron transport layer/electron injection layer structure, a hole blocking layer/electron transport layer/electron injection layer structure, or the like, wherein the layers of each structure may be stacked on the emission layer in its respective stated order, but the structure of the electron transport region is not limited thereto.

The electron transport region (e.g., a hole blocking layer or an electron transport layer in the electron transport region) may include a metal-free compound including at least one TT electron-deficient nitrogen-containing C₁-C₆₀ cyclic group.

In an embodiment, the electron transport region may include a compound represented by Formula 601:

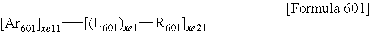

In Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁) (Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described herein with regard to Q₁,
xe21 may be 1, 2, 3, 4, or 5, and
at least one of Ar₆₀₁, L₆₀₁, and R₆₀₁ may each independently be a IT electron-deficient nitrogen-containing C₁-C₆₀ cyclic group that is unsubstituted or substituted with at least one R₁₀ₐ.

In an embodiment, in Formula 601, when xe11 is 2 or more, two or more of Ar₆₀₁ may be linked to each other via a single bond.

In embodiments, in Formula 601, Ar₆₀₁ may be a substituted or unsubstituted anthracene group.

In embodiments, the electron transport region may include a compound represented by Formula 601-1:

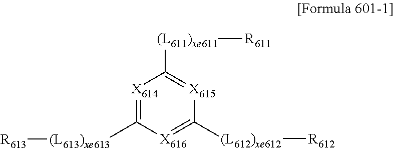

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described above with regard to L₆₀₁,
xe611 to xe613 may each independently be the same as described above with regard to xe1,
R₆₁₁ to R₆₁₃ may each independently be the same as described above with regard to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, in Formulae 601 and 601-1, xe1 and xe611 to xe613 may each independently be 0, 1, or 2.

The electron transport region may include: one of Compounds ET1 to ET45; 2,9-dimethyl-4,7-diphenyl-1,10-phenanthroline (BCP); 4,7-diphenyl-1,10-phenanthroline (Bphen); Alq₃; BAlq; TAZ; NTAZ; or any combination thereof:

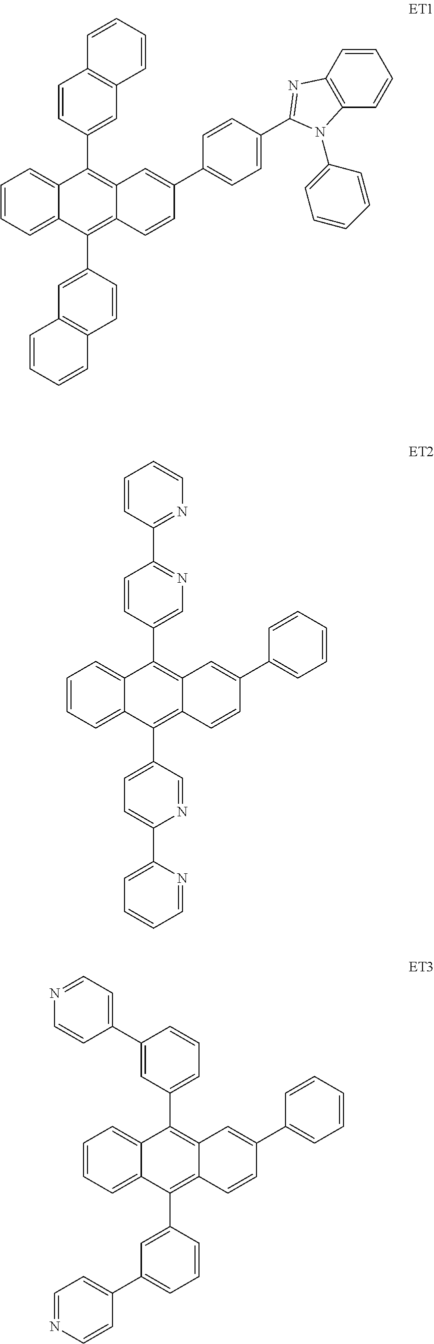 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

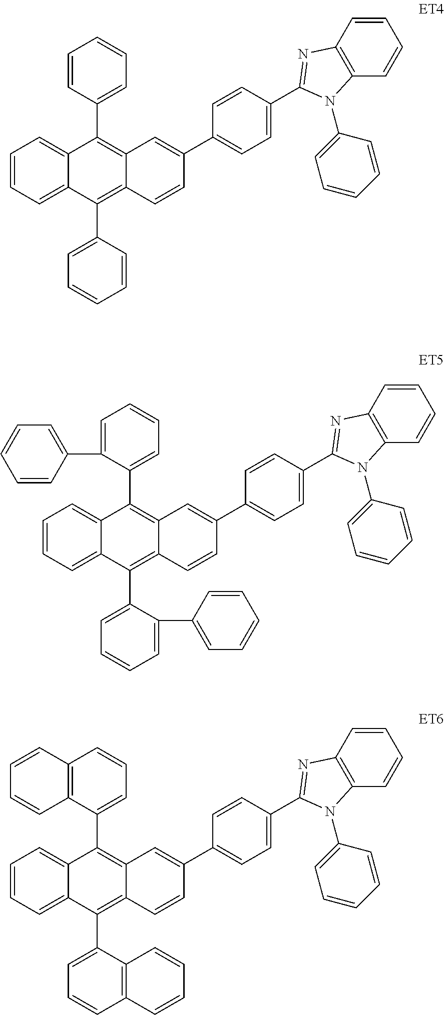 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

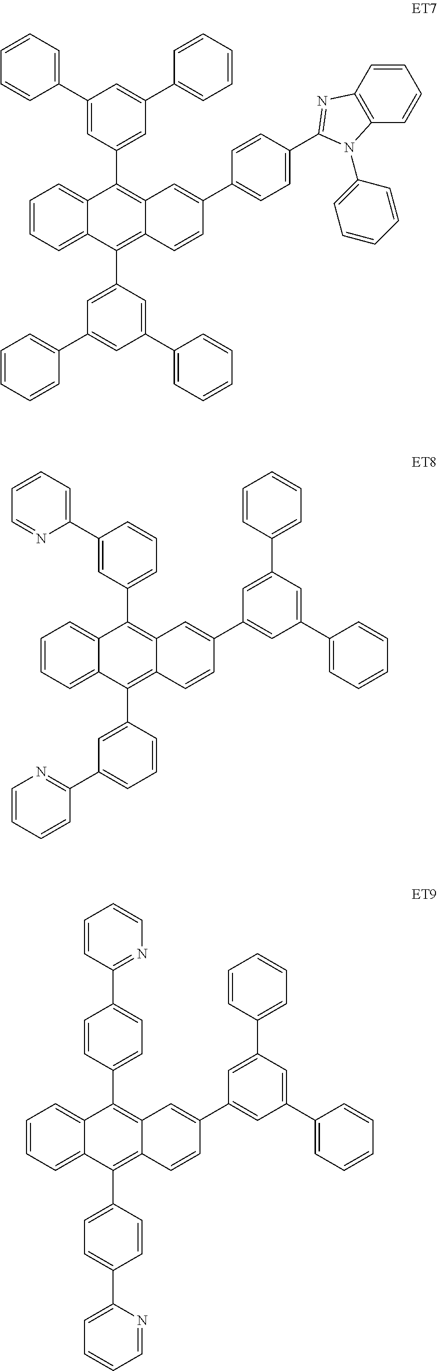 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

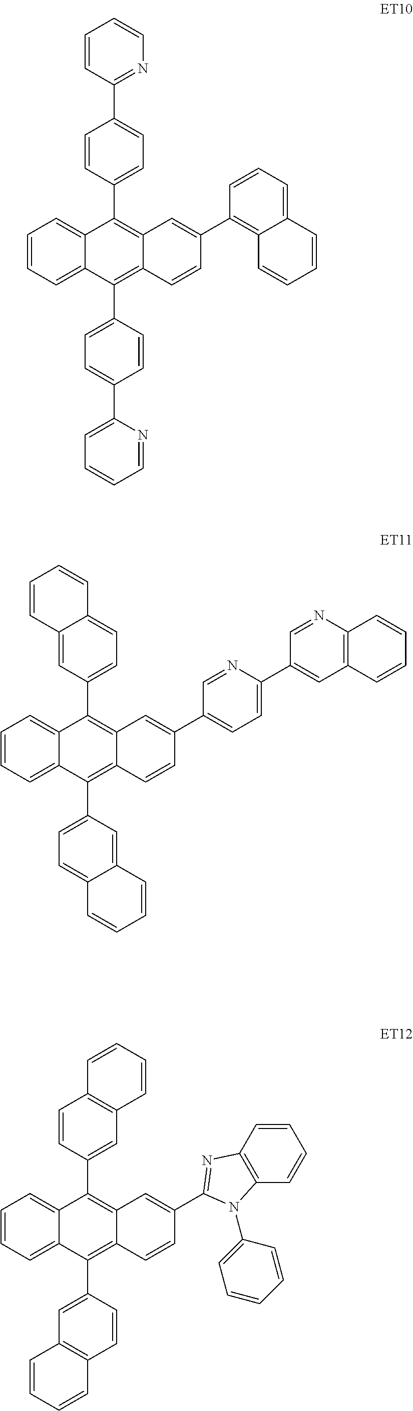 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

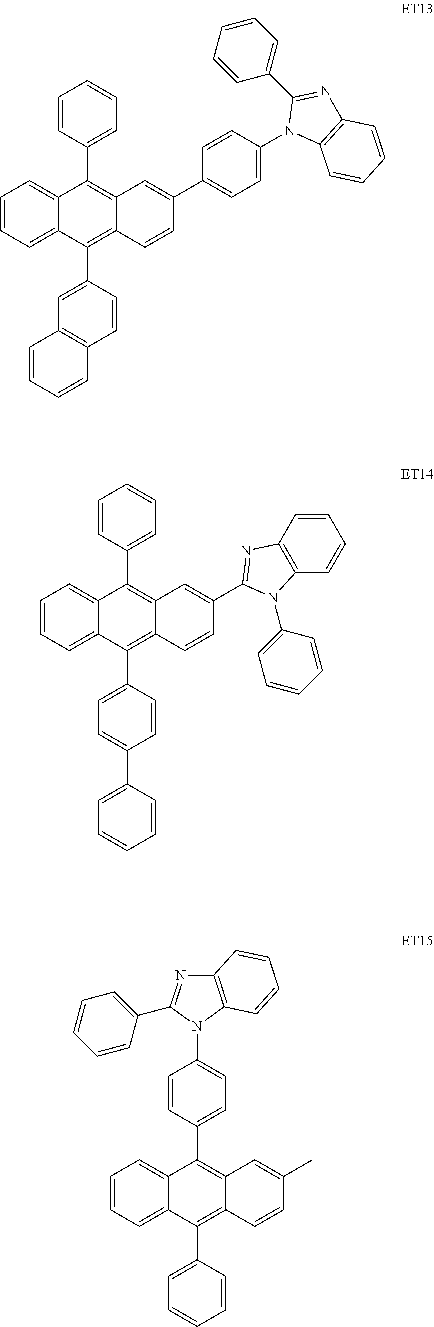 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

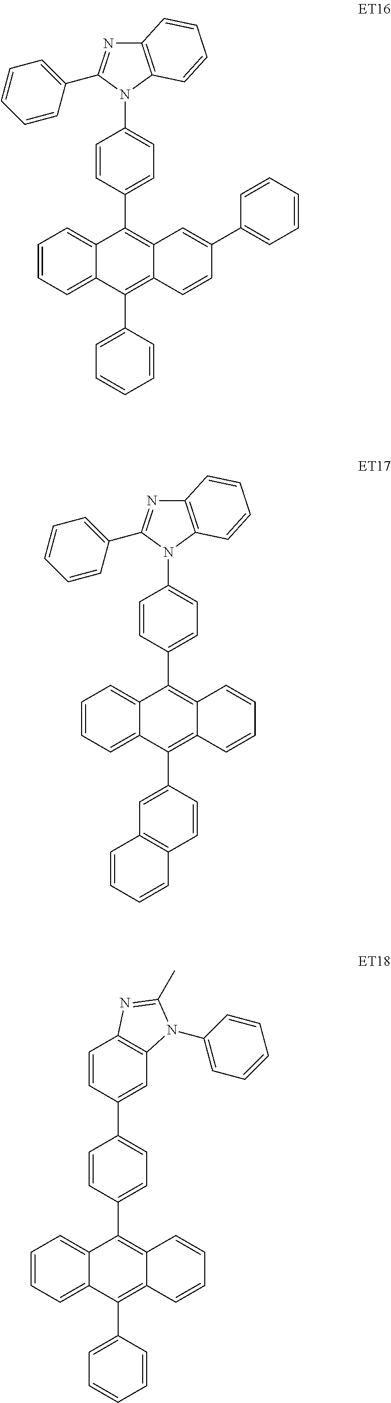 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

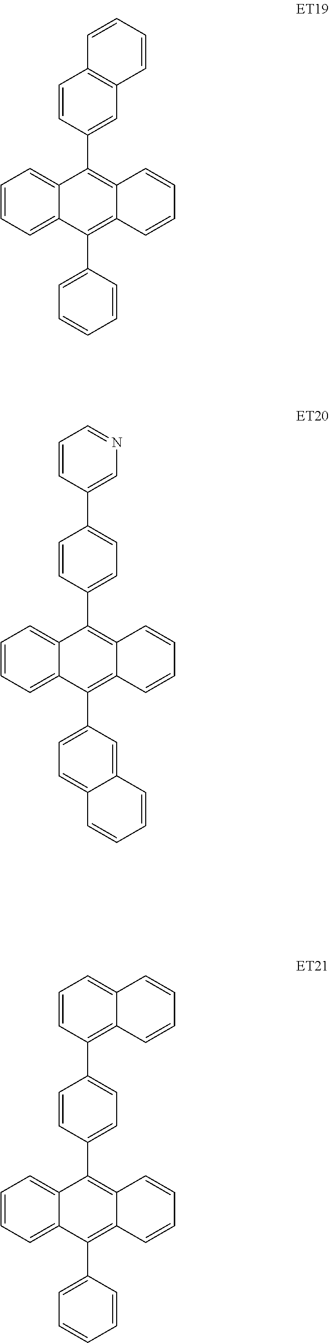

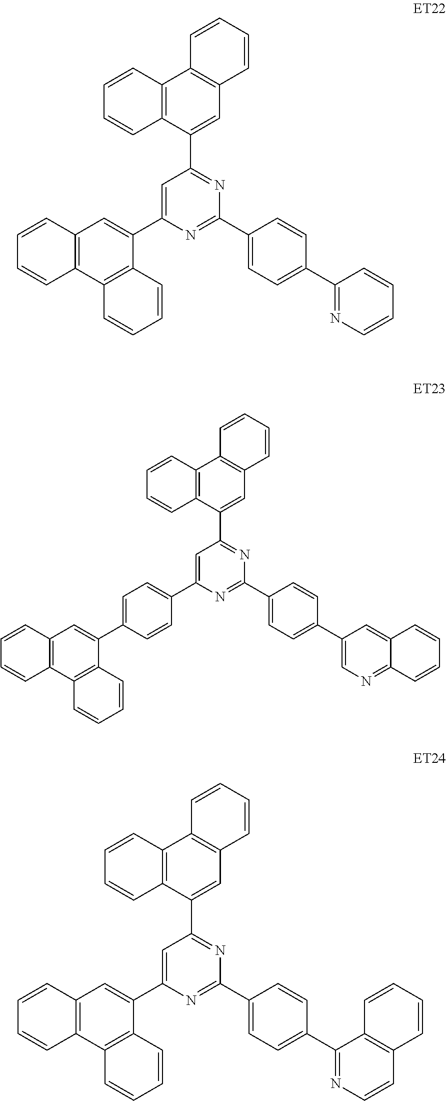 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

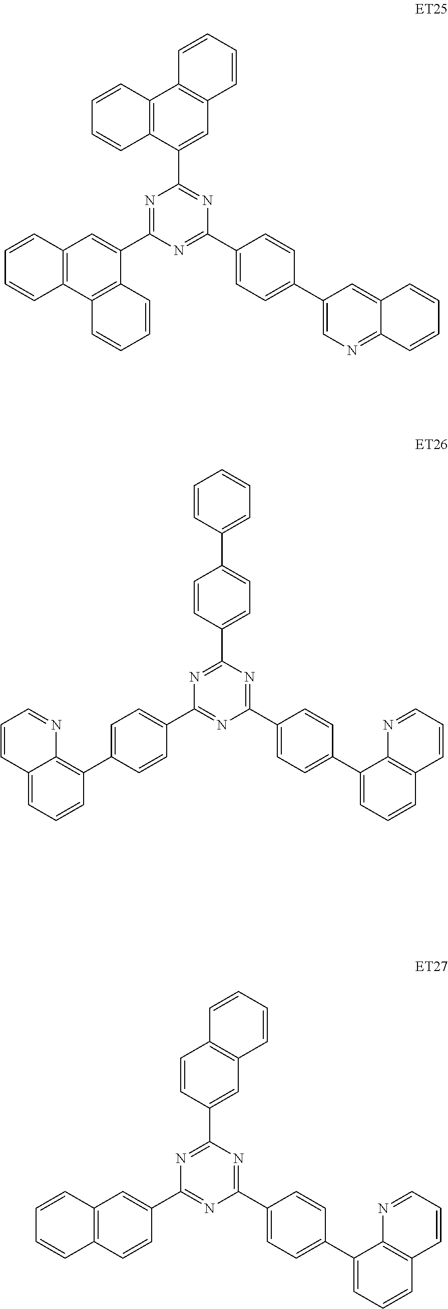 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

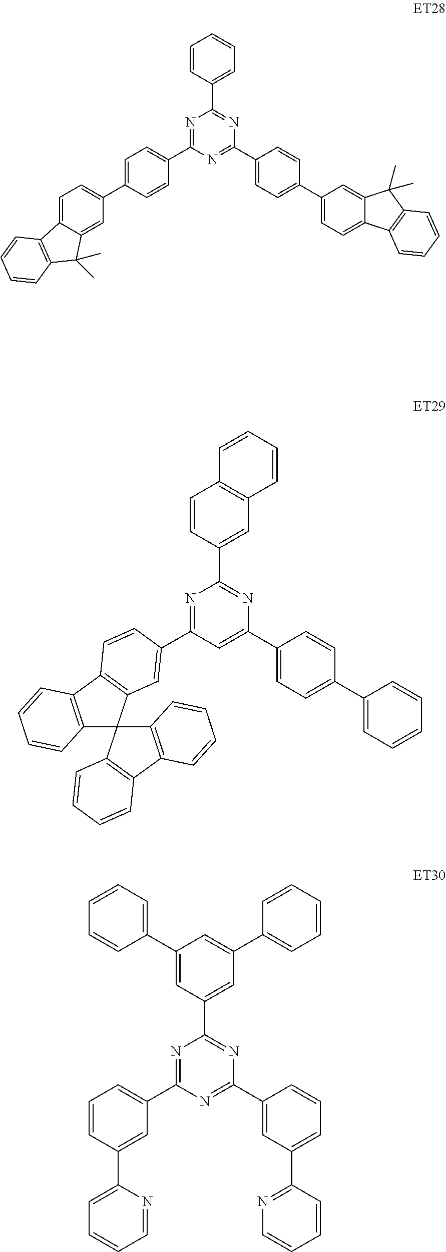 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

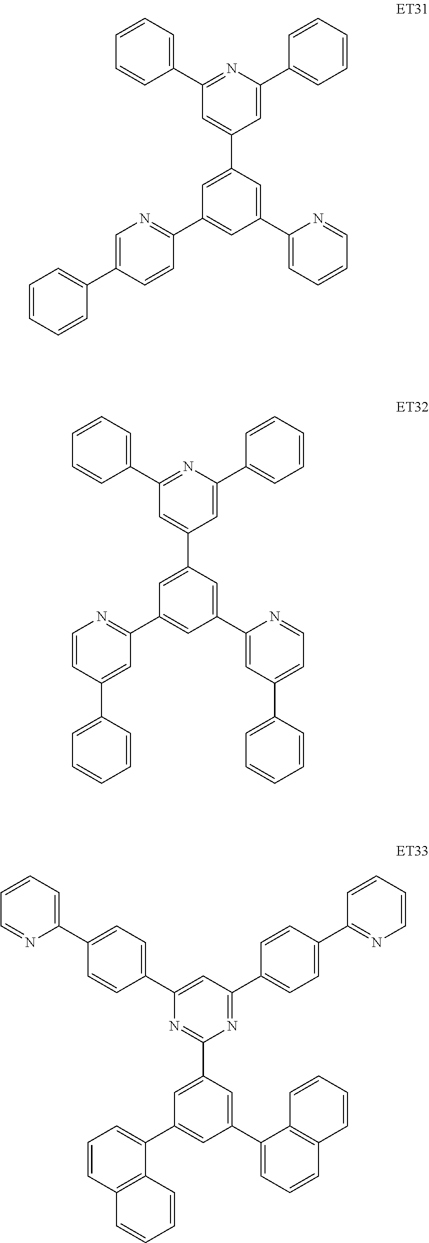 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

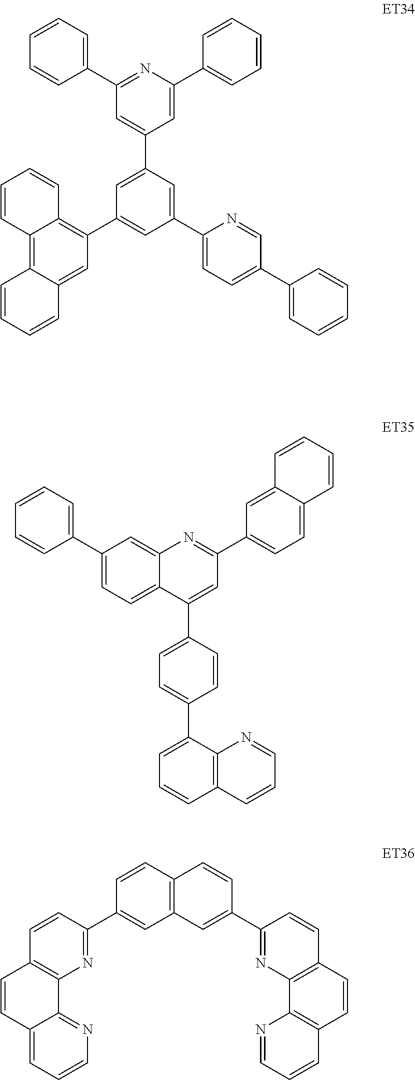 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

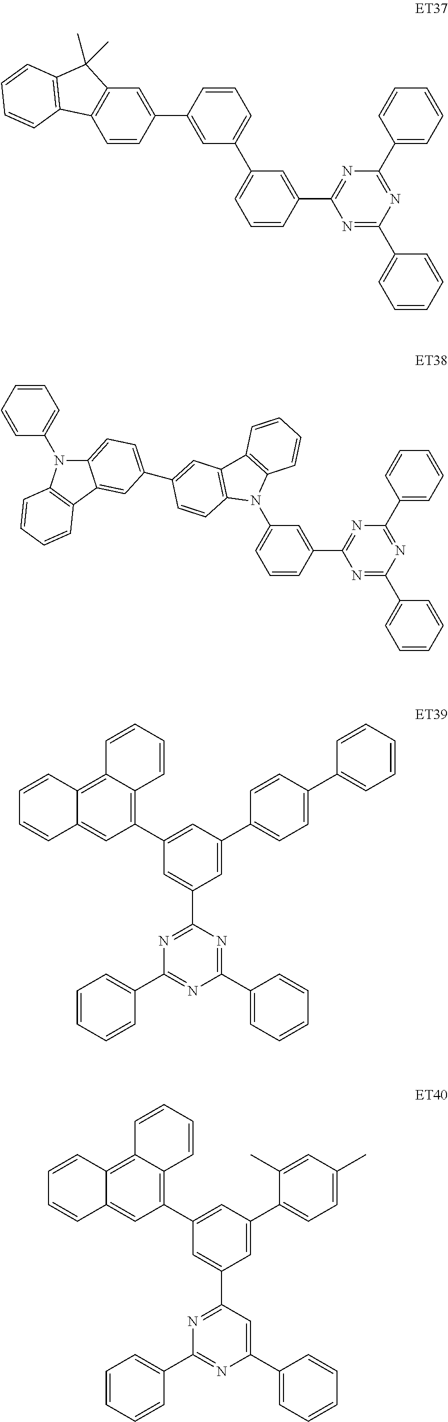 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

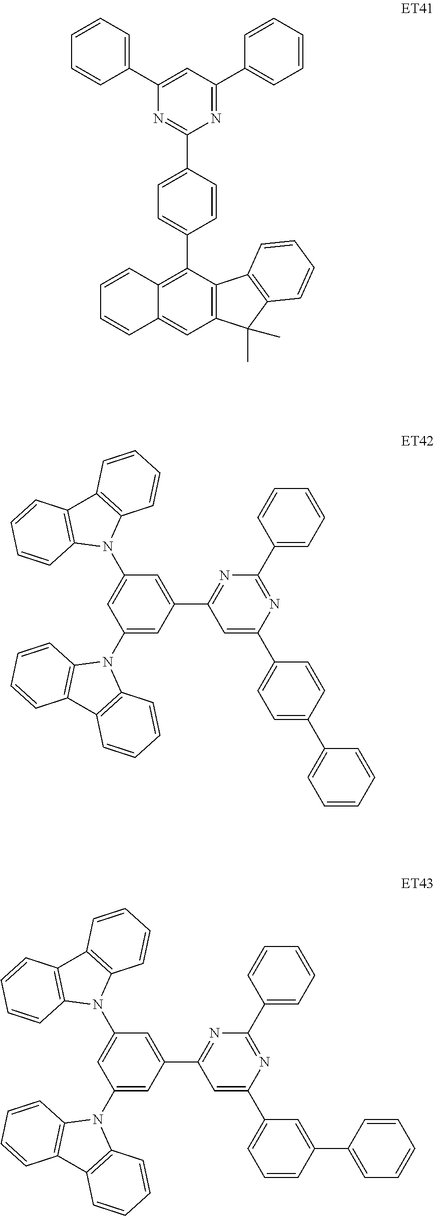 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

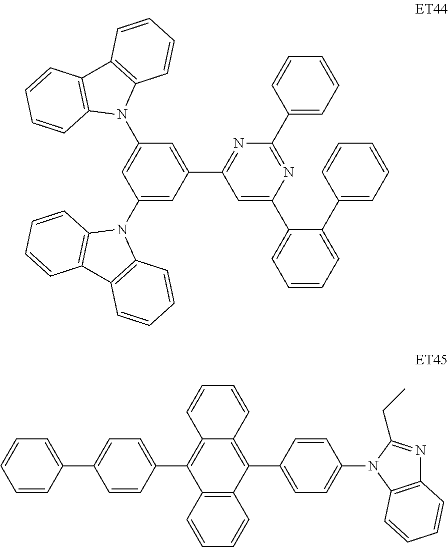 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

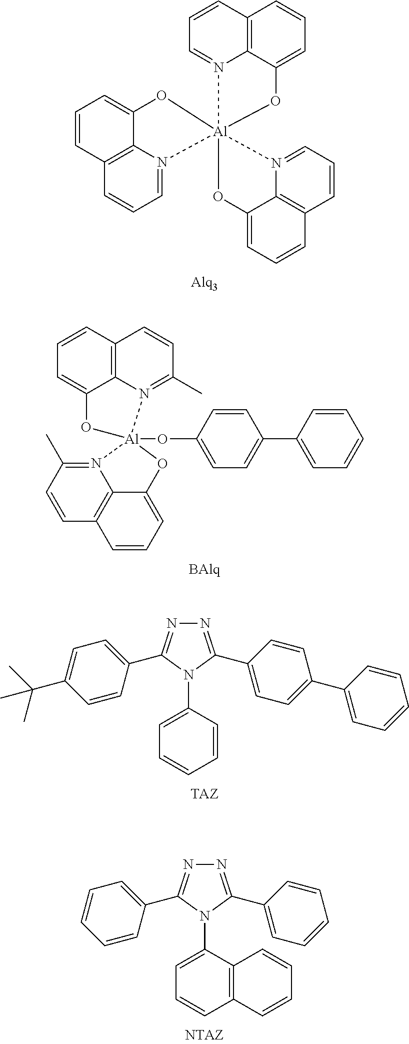

A thickness of the electron transport region may be in a range of about 100 Å to about 5,000 Å. For example, the thickness of the electron transport region may be in a range of about 160 Å to about 4,000 Å. When the electron transport region includes a hole blocking layer, an electron transport layer, or any combination thereof, a thickness of the hole blocking layer may be in a range of about 20 Å to about 1,000 Å and a thickness of the electron transport layer may be in a range of about 100 Å to about 1,000 Å. For example, the thickness of the hole blocking layer may be in a range of about 30 Å to about 300 Å. For example, the thickness of the electron transport layer may be in a range of about 150 Å to about 500 Å. When the thickness(es) of the hole blocking layer and/or the electron transport layer is(are) within these ranges, satisfactory electron transporting characteristics may be obtained without a substantial increase in driving voltage.

The electron transport region (e.g., an electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion.

A ligand coordinated with the metal ion of an alkali metal complex or an alkaline earth-metal complex may each independently include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

In an embodiment, the metal-containing material may include a Li complex. The Li complex may include, for example, Compound ET-D1 (LiQ) or Compound ET-D2:

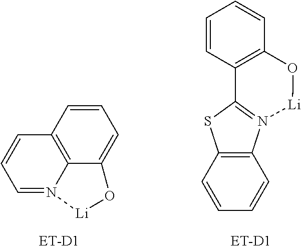

The electron transport region may include an electron injection layer that facilitates the injection of electrons from the second electrode 150. The electron injection layer may contact (e.g., directly contact) the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, or iodides), tellurides, or any combination of thereof of each of the alkali metal, the alkaline earth metal, and the rare earth metal.

The alkali metal-containing compound may include: an alkali metal oxide, such as Li₂O, Cs₂O, or K₂O; an alkali metal halide, such as LiF, NaF, CsF, KF, LiI, NaI, CsI, or KI; or any combination thereof. The alkaline earth metal-containing compound may include an alkaline earth metal compound, such as BaO, SrO, CaO, BaₓSr₁₋ₓO (wherein x is a real number satisfying 0<x<1), or BaₓCa₁₋ₓO (wherein x is a real number satisfying 0<x<1).

The rare earth metal-containing compound may include YbF₃, ScF₃, SC₂O₃, Y₂O₃, Ce₂O₃, GdF₃, TbF₃, YbI₃, ScI₃, TbI₃, or any combination thereof. In embodiments, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include an alkali metal ion, an alkaline earth metal ion, or a rare earth metal as described above; and a ligand bonded to the metal ion (e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In embodiments, the electron injection layer may further include an organic material (e.g., a compound represented by Formula 601).

In an embodiment, the electron injection layer may consist of an alkali metal-containing compound (e.g., alkali metal halide); or the electron injection layer may consist of an alkali metal-containing compound (e.g., alkali metal halide), and an alkali metal, an alkaline earth metal, a rare earth metal, or any combination thereof. For example, the electron injection layer may be a KI:Yb co-deposition layer, an RbI:Yb co-deposition layer, or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth metal complex, the rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within these ranges, satisfactory electron injection characteristics may be obtained without a substantial increase in driving voltage.

### [Second Electrode 150]

The second electrode 150 may be disposed on the interlayer 130 as described above. The second electrode 150 may be a cathode, which is an electron injection electrode. when the second electrode 150 is a cathode, a material for forming the second electrode 150 may include a material having a low work function, e.g., a metal, an alloy, an electrically conductive compound, or any combination thereof.

The second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multi-layered structure.

### [Capping Layer]

The light-emitting device 10 may include a first capping layer outside the first electrode 110, and/or a second capping layer outside the second electrode 150. In embodiments, the light-emitting device 10 may have a structure in which the first capping layer, the first electrode 110, the interlayer 130, and the second electrode 150 are stacked in the stated order, a structure in which the first electrode 110, the interlayer 130, the second electrode 150, and the second capping layer are stacked in the stated order, or a structure in which the first capping layer, the first electrode 110, the interlayer 130, the second electrode 150, and the second capping layer are stacked in the stated order.

In the light-emitting device 10, light emitted from the emission layer in the interlayer 130 may pass through the first electrode 110, which may be a semi-transmissive electrode or a transmissive electrode, and through the first capping layer to the outside. In the light-emitting device 10, light emitted from the emission layer in the interlayer 130 may pass through the second electrode 150, which may be a semi-transmissive electrode or a transmissive electrode, and through the second capping layer to the outside.

The first capping layer and the second capping layer may each increase external luminescence efficiency through the principle of constructive interference. Accordingly, the optical extraction efficiency of the light-emitting device 10 may be increased, thus improving the luminescence efficiency of the light-emitting device 10.

Each of the first capping layer and the second capping layer may include a material having a refractive index greater than or equal to about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof. In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In embodiments, at least one of the first capping layer and the second capping layer may each independently include: one of Compounds HT28 to HT33; one of Compounds CP1 to CP6; β-NPB; or any combination thereof:

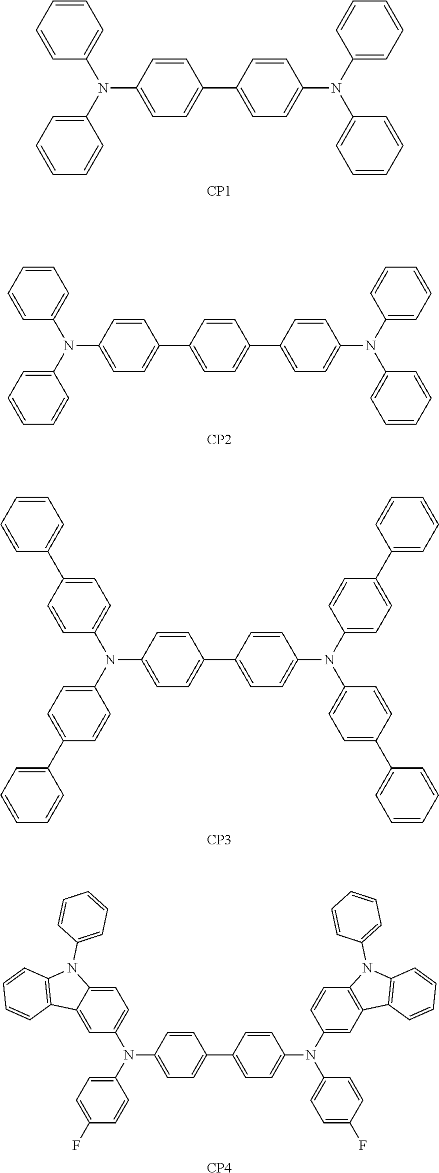

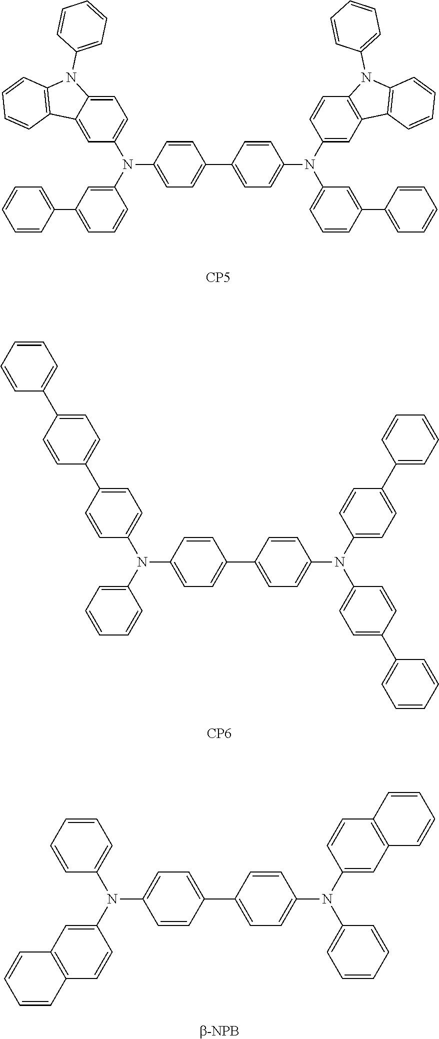 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; "CP5" ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; "CP6" ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various electronic apparatuses. For example, the electronic apparatus including the light-emitting device may be a light-emitting apparatus, an authentication apparatus, or the like.

The electronic apparatus (e.g., a light-emitting apparatus) may further include, in addition to the light-emitting device, a color filter, a color conversion layer, or a color filter and a color conversion layer. The color filter and/or the color conversion layer may be disposed on at least one traveling direction of light emitted from the light-emitting device. In an embodiment, light emitted from the light-emitting device may be blue light or white light. The light-emitting device may be the same as described above.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining film may be located between the subpixels to define each subpixel.

The color filter may further include color filter areas and light-shielding patterns between the color filter areas, and the color conversion layer may further include color conversion areas and light-shielding patterns between color conversion areas.

The color filter areas (or color conversion areas) may include: a first area emitting first color light; a second area emitting second color light, and/or a third area emitting third color light, and the first color light, the second color light, and/or the third color light may have different maximum emission wavelengths. For example, the first color light may be red light, the second color light may be green light, and the third color light may be blue light. For example, the color filter areas (or the color conversion areas) may include quantum dots. In embodiments, the first area may include red quantum dots, the second area may include green quantum dots, and the third area may not include a quantum dot. The quantum dot may be the same as described herein. The first area, the second area, and/or the third area may each further include a scatterer.

The regions including quantum dots may be formed using the composition including the quantum dot-containing complex, according to an embodiment.

For example, the light-emitting device may emit first light, the first area may absorb the first light to emit 1-1 color light, the second area may absorb the first light to emit 2-1 color light, and the third area may absorb the first light to emit 3-1 color light. In this embodiment, the 1-1 color light, the 2-1 color light, and the 3-1 color light may have different maximum emission wavelengths. In embodiments, the first light may be blue light, the 1-1 color light may be red light, the 2-1 color light may be green light, and the 3-1 color light may be blue light.

The electronic apparatus may further include a thin-film transistor, in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, and the like.

The active layer may include crystalline silicon, amorphous silicon, an organic semiconductor, an oxide semiconductor, and the like.

The electronic apparatus may further include an encapsulation unit for encapsulating the light-emitting device. The encapsulation unit may be located between the color filter and/or the color conversion layer and the light-emitting device. The encapsulation unit may allow light to pass to the outside from the light-emitting device and at the same time may prevent air and moisture from permeating the light-emitting device. The encapsulation unit may be an encapsulation substrate including a transparent glass substrate or a plastic substrate. The encapsulation unit may be a thin-film encapsulation layer including at least one of an organic layer and/or an inorganic layer. When the encapsulation unit is a thin-film encapsulation layer, the electronic apparatus may be flexible.

In addition to the color filter and/or the color conversion layer, various functional layers may be disposed on the encapsulation unit depending on the use of the electronic apparatus. Examples of the functional layer may include a touch screen layer, a polarizing layer, and the like. The touch screen layer may be a resistive touch screen layer, a capacitive touch screen layer, or an infrared beam touch screen layer.

The authentication apparatus may be, for example, a biometric authentication apparatus that identifies an individual by using biometric information of a living body (e.g., a fingertip, a pupil, or the like).

The authentication apparatus may further include, in addition to the light-emitting device as described above, a biometric information collector.

The electronic apparatus may be applied to various displays, an optical source, lighting, a personal computer (e.g., a mobile personal computer), a mobile phone, a digital camera, an electronic note, an electronic dictionary, an electronic game console, a medical device (e.g., an electronic thermometer, a blood pressure meter, a glucometer, a pulse measurement device, a pulse wave measuring device, an electrocardiogram recorder, an ultrasonic diagnostic device, or an endoscope display), a fish finder, various measurement devices, gauges (e.g., gauges of an automobile, an airplane, or a ship), and a projector.

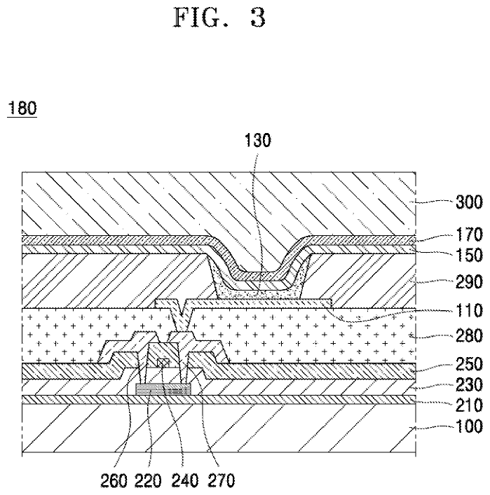

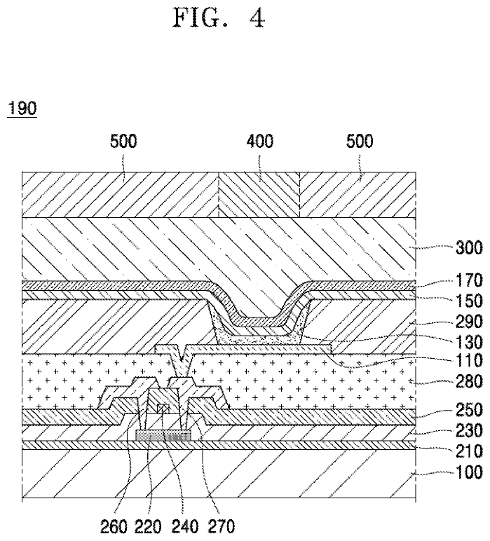

### Description of FIGS. 3 and 4

FIG. 3 is a schematic cross-sectional view of an electronic apparatus 180 according to an embodiment.

The electronic apparatus 180 in FIG. 3 may include a substrate 100, a thin-film transistor (TFT), a light-emitting device, and an encapsulation unit 300 encapsulating the light-emitting device.

The substrate 100 may be a flexible substrate, a glass substrate, or a metal substrate. A buffer layer 210 may be on the substrate 100. The buffer layer 210 may prevent penetration of impurities through the substrate 100 and provide a flat surface on the substrate 100.

A TFT may be on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor, and include a source region, a drain region, and a channel region.

A gate insulating film 230 for insulating the active layer 220 and the gate electrode 240 may be on the active layer 220, and the gate electrode 240 may be on the gate insulating film 230.

An interlayer insulating film 250 may be on the gate electrode 240. The interlayer insulating film 250 may be between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device includes the first electrode 110, the interlayer 130, and the second electrode 150.

The first electrode 110 may be on the passivation layer 280. The passivation layer 280 may not fully cover the drain electrode 270 and may expose an area of the drain electrode 270. The first electrode 110 may be electrically connected to the exposed area of the drain electrode 270.

A pixel-defining layer 290 including an insulating material may be arranged on the first electrode 110. The pixel-defining layer 290 may expose a certain area of the first electrode 110, and the interlayer 130 may be formed in the exposed area of the first electrode 110. The pixel-defining layer 290 may be a polyimide or a polyacrylic organic film. Although not shown in FIG. 3, at least some layers of the interlayer 130 may extend to the upper portion of the pixel-defining layer 290 and may be provided in the form of a common layer.

The second electrode 150 may be arranged on the interlayer 130, and a capping layer 170 may be further included on the second electrode 150. The capping layer 170 may be formed to cover the second electrode 150.

The encapsulation unit 300 may be arranged on the capping layer 170. The encapsulation unit 300 may be arranged on the light-emitting device to protect the light-emitting device from moisture or oxygen. The encapsulation unit 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyl disiloxane, an acrylic resin (e.g., polymethyl methacrylate, polyacrylic acid, or the like), an epoxy-based resin (e.g., aliphatic glycidyl ether (AGE) or the like), or any combination thereof; or any combination of the inorganic film and the organic film.

FIG. 4 is a schematic cross-sectional view of an electronic apparatus 190 according to another embodiment.

The electronic apparatus 190 shown in FIG. 4 may differ from the electronic apparatus shown in FIG. 3, at least in that a light-shielding pattern 500 and a functional area 400 are further included on the encapsulation unit 300. The functional area 400 may be a color filter area, a color conversion area, or a combination of the color filter area and the color conversion area. In an embodiment, the light-emitting device included in the electronic apparatus of FIG. 4 may be a tandem light-emitting device.

### [Manufacturing Method]

Respective layers included in the hole transport region, the emission layer, respective layers included in the electron transport region, and the like may be formed in a certain region by using various methods such as vacuum deposition, spin coating, casting, a Langmuir-Blodgett (LB) method, ink-jet printing, laser printing, and laser-induced thermal imaging.

The color filter region, the color conversion region, and the like may be formed in a certain region using spin coating, casting, inkjet printing, or the like.

When respective layers included in the hole transport region, the emission layer, and respective layers included in the electron transport region are formed by vacuum deposition, the vacuum deposition may be performed at a deposition temperature of about 100° C. to about 500° C., a vacuum degree of about 10-8 torr to about 10-3 torr, and a deposition rate of about 0.01 Å/sec to about 100 Å/sec, depending on a material to be included in each layer and the structure of each layer to be formed.

When layers constituting the hole transport region, an emission layer, and layers constituting the electron transport region are each formed by spin coating, the spin coating may be performed at a coating rate of about 2,000 rpm to about 5,000 rpm and at a heat treatment temperature of about 80° C. to about 200° C. in consideration of a material to be included in each layer and the structure of each layer to be formed.

The composition according to embodiments may be used in a solution process, such as spin coating or inkjet printing.

### [Definitions of Substituents]

The term “C₃-C₆₀ carbocyclic group” as used herein may be a cyclic group consisting of carbon atoms only and having 3 to 60 carbon atoms as ring-forming atoms, and the term “C₁-C₆₀ heterocyclic group” as used herein may be a cyclic group having 1 to 60 carbon atoms in addition to at least one heteroatom as ring-forming atoms other than carbon. The C₃-C₆₀ carbocyclic group and the C₁-C₆₀ heterocyclic group may each be a monocyclic group consisting of one ring or a polycyclic group in which at least two rings are condensed with each other. For example, the number of ring-forming atoms in a C₁-C₆₀ heterocyclic group may be in a range of 3 to 61.

The term “cyclic group” as used herein may be a C₃-C₆₀ carbocyclic group or a C₁-C₆₀ heterocyclic group.

The term “IT electron-rich C₃-C₆₀ cyclic group” as used herein may be a cyclic group having 3 to 60 carbon atoms and may not include *—N═*′ as a ring-forming moiety, and the term “TT electron-deficient nitrogen-containing C₁-C₆₀ cyclic group” as used herein may be a heterocyclic group having 1 to 60 carbon atoms and may include *—N═*′ as a ring-forming moiety.

In embodiments,
a C₃-C₆₀ carbocyclic group may be a T1 group or a group in which at least two T1 groups are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which at least two T2 groups are condensed with each other, or a group in which at least one T2 group and at least one T1 group are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),
a π electron-rich C₃-C₆₀ cyclic group may be a T1 group, a group in which at least two T1 groups are condensed with each other, a T3 group, a group in which at least two T3 groups are condensed with each other, or a group in which at least one T3 group and at least one T1 group are condensed with each other (e.g., a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran a group, a benzofurodibenzothiophene group, benzothienodibenzothiophene group, or the like),
a π electron-deficient nitrogen-containing C₁-C₆₀ cyclic group may be a T4 group, a group in which at least two T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),
wherein the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, C₃-“C₆₀ carbocyclic group”, “C₁-C₆₀ heterocyclic group”, “TT electron-rich C₃-C₆₀ cyclic group”, or “TT electron-deficient nitrogen-containing C₁-C₆₀ cyclic group” as used herein may each be a group condensed with any cyclic group, a monovalent group, or a polyvalent group (e.g., a divalent group, a trivalent group, a tetravalent group, or the like) depending on the structure of a formula for which the corresponding term is used. For example, “a benzene group” may be a benzo group, a phenyl group, a phenylene group, or the like, which may be readily understood by one of ordinary skill in the art depending on the structure of the formula including the “benzene group.”

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₅-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched aliphatic hydrocarbon monovalent group having 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, and a butenyl group. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group and a propynyl group. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, and an isopropyloxy group.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group having 1 to 10 carbon atoms and including at least one heteroatom other than carbon atoms as a ring-forming atom, and examples thereof may include a 1,2,3,4-oxatriazolidinyl group, a tetrahydrofuranyl group, a and tetrahydrothiophenyl group. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in the ring thereof and is not aromatic, and examples thereof may include a cyclopentenyl group, a cyclohexenyl group, and a cycloheptenyl group. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group of 1 to 10 carbon atoms, further including at least one heteroatom other than carbon atoms as a ring-forming atom, and having at least one double bond in the ring thereof. Examples of a C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system having 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the two or more respective rings may be condensed with each other.

The term “C₁-C₆₀ heteroaryl group” as used herein may be a monovalent group having a heterocyclic aromatic system further including at least one heteroatom other than carbon atoms as a ring-forming atom and having 1 to 60 carbon atoms. The term “C₁-C₆₀ heteroarylene group” as used herein may be a divalent group having a heterocyclic aromatic system further including at least one heteroatom other than carbon atoms as a ring-forming atom. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the two or more respective rings may be condensed with each other.

The term “monovalent non-aromatic condensed polycyclic group” as used herein may be a monovalent group that has two or more condensed rings and only carbon atoms (e.g., having 8 to 60 carbon atoms) as ring-forming atoms, wherein the molecular structure when considered as a whole is non-aromatic. Examples of a monovalent non-aromatic condensed polycyclic group may include an indenyl group, a fluorenyl group, a spiro-bifluorenyl group, a benzofluorenyl group, an indenophenanthrenyl group, and an indenoanthracenyl group. The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group that has two or more condensed rings and at least one heteroatom other than carbon atoms (e.g., having 1 to 60 carbon atoms) as a ring-forming atom, wherein the molecular structure when considered as a whole is non-aromatic. Examples of a monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆) (A₁₀₇) (wherein A₁₀₆ may be a C₁-C₅₉ alkylene group, and A₁₀₇ may be a C₁-C₅₉ heteroaryl group).

In the specification, the group “R₁₀ₐ” may be:
deuterium, —F, —Cl, —Br, —I, a hydroxyl group, a cyano group, or a nitro group; a C₁-C₆₀ alkyl group, a C₂-C₆₀ alkenyl group, a C₂-C₆₀ alkynyl group, or a C₁-C₆₀ alkoxy group, each of which is unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each of which is unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁) (Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁) (Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroaryl alkyl group, each of which is unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, or any combination thereof.

A third-row transition metal as used herein may include hafnium (Hf), tantalum (Ta), tungsten (W), rhenium (Re), osmium (Os), iridium (Ir), platinum (Pt), gold (Au), or the like.

In the specification, “Ph” refers to a phenyl group, “Me” refers to a methyl group, “Et” refers to an ethyl group, “ter-Bu” or “But” each refer to a tert-butyl group, and “OMe” refers to a methoxy group.

The term “biphenyl group” as used herein may be “a phenyl group substituted with a phenyl group.” For example, the “biphenyl group” may be “a substituted phenyl group” having a “C₆-C₆₀ aryl group” as a substituent.

The term “terphenyl group” as used herein may be “a phenyl group substituted with a biphenyl group”. For example, the “terphenyl group” may be a “substituted phenyl group” having a “C₆-C₆₀ aryl group substituted with a C₆-C₆₀ aryl group” as a substituent.

A maximum number of carbon atoms as recited in the specification is provided only as an example. For example, a maximum carbon number of 60 in a C₁-C₆₀ alkyl group is only an example, and the definition of an alkyl group may be equally applied to a C₁-C₂₀ alkyl group. The same may also apply to other cases.

The symbols * and *′ as used herein, unless defined otherwise, each refer to a binding site to a neighboring atom in a corresponding formula.

Hereinafter, a compound and a light-emitting device according to embodiments will be described in more detail with reference to the Examples and the Comparative Examples.

### EXAMPLES

### Synthesis of Ligand A

1 mmol of lauryl acrylate, 1 mmol of 2-(2-(2-(2-(2-phenoxyethoxy)ethoxy)ethoxy)ethoxy)ethyl acrylate, and 1 mmol of glycidyl methacrylate were added to 10 ml of cyclohexyl acetate as a solvent, and 0.001 mmol of diphenyl(2,4,6-trimethylbenzoyl)phosphine oxide (TPO) as an initiator was added thereto, followed by stirring at room temperature while exposure to UV (395 nm, 10 s), thereby completing the synthesis of Compound 1.

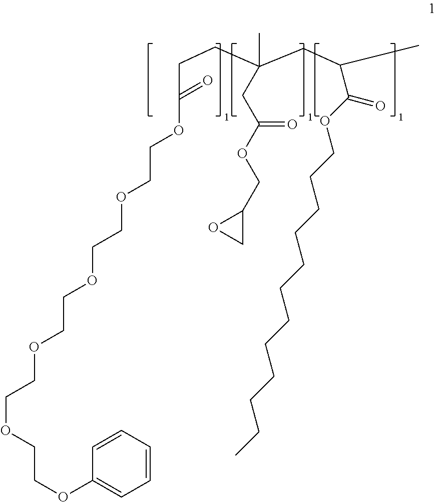

### Preparation of Quantum Dot-Containing Complex

### Example 1

1 g (25 wt %) of a quantum dot (a ZnS shell and a Group II-V core, 10 nm) with a native ligand [lauric acid] as ligands B coordinated thereto was added to cyclohexyl acetate, and stirred at room temperature for 1 hour. 0.4 g of Compound 1 as ligands A was added, and stirred at 70° C. for 2 hours.

0.004 g of N-ethylene diamine was added, followed by heating at 100° C. for 30 minutes, to allow thermosetting moieties of ligands A to react.

Hexane was added in an amount of 10 times that of a reaction solution, followed by centrifugation (9500 rpm/3 min), and the obtained precipitate was vacuum-dried to thereby obtain a quantum dot-containing complex.

### Comparative Example 1

A quantum dot-containing complex was prepared in the same manner as in Example 1, except that 2,5,8,11,14-pentaoxatriacontane was used as ligands A instead of Compound 1, and heating was not performed.

### Comparative Example 2

A quantum dot-containing complex was prepared in the same manner as in Example 1, except that mPEG₄COOH was used as ligands A instead of Compound 1, and heating was not performed.

### Comparative Example 3

A quantum dot-containing complex was prepared in the same manner as in Example 1, except that Compound 100 was used as ligand A instead of Compound 1, and exposure to UV (395 nm) was conducted for 10 seconds without heating, allowing photocurable moieties (an acrylate site) of Compound 100 to react.

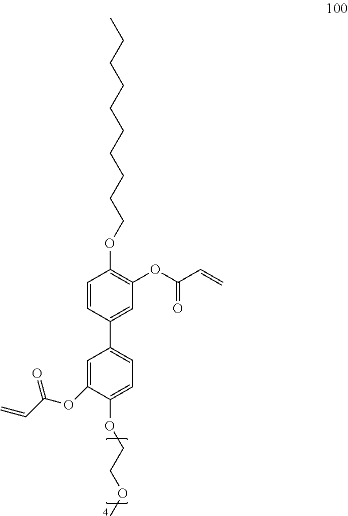

### Stability Evaluation

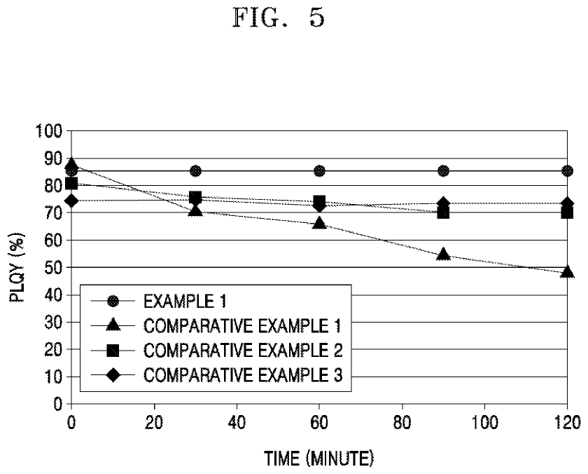

25 wt % of each of the quantum dot-containing complexes of Example 1 and Comparative Examples 1 to 3 was added to distilled water, and stirred at room temperature for 1 hour. Each solution was left for 120 minutes, and photoluminescence quantum yield (PLQY) was measured under UV at 450 nm every 30 minutes, and the results thereof are illustrated in FIG. 5.

Referring to FIG. 5, it can be confirmed that the quantum dot-containing complex of Example 1 exhibits higher stability than the quantum dot-containing complexes of Comparative Examples 1 to 3. In the case of Comparative Example 3, it was confirmed that the PLQY over time was well maintained, but damage occurred on the surface of the quantum dot during photocuring, and the initial PLQY fell to about 78.0% after curing.

### Preparation of Quantum Dot Composition

### Example 2

0.375 g of the quantum dot-containing complex of Example 1, and 0.526 g of 1,6-hexanediol diacrylate as a crosslinkable monomer were mixed, followed by shaking for 12 hours, and 0.08 g of TiO₂ and 0.01 g of diphenyl(2,4,6-trimethylbenzoyl)phosphine oxide as a photoinitiator were added thereto, followed by shaking for 3 hours, to thereby prepare a composition.

### Comparative Example 4

A composition was prepared in the same manner as in Example 2, except that the quantum dot-containing complex of Comparative Example 1 was used.

### Comparative Example 5

A composition was prepared in the same manner as in Example 2, except that the quantum dot-containing complex of Comparative Example 2 was used.

### Comparative Example 6

A composition was prepared in the same manner as in Example 2, except that the quantum dot-containing complex of Comparative Example 3 was used.

### Manufacture of Electronic Apparatus

### Example 3

As illustrated in FIG. 4, an electronic apparatus was manufactured by forming a color filter area in a functional area 400 by inkjet printing using the quantum dot composition of Example 2.

### Comparative Example 7

An electronic apparatus was manufactured in the same manner as in Example 3, except that the quantum dot composition of Comparative Example 4 was used.

### Comparative Example 8

An electronic apparatus was manufactured in the same manner as in Example 3, except that the quantum dot composition of Comparative Example 5 was used.

### Comparative Example 9

An electronic apparatus was manufactured in the same manner as in Example 3, except that the quantum dot composition of Comparative Example 6 was used.

As a result of operating the electronic apparatuses of Example 3 and Comparative Examples 7 to 9 for 10,000 hours, and measuring the PLQY of a color filter of each apparatus, it was confirmed that Example 3 showed almost no change, whereas Comparative Examples 7 to 9 showed a remarkably reduced PLQY. This fits well with the stability evaluation results of the quantum dot-containing complex.

While the disclosure has been described with reference to example embodiments illustrated in the drawings, these embodiments are provided herein for illustrative purpose only, and one of ordinary skill in the art may understand that the embodiments may include various modifications and equivalent embodiments thereof. Accordingly, the scope of the disclosure should be determined by the technical idea of the claims.

As is apparent from the foregoing description, a quantum dot-containing complex according to an embodiment may have excellent stability due to having no defect due to ligand substitution on a surface of a quantum dot, and an electronic apparatus using the same may have excellent efficiency.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A quantum dot-containing complex comprising:
a quantum dot; and
ligands A and ligands B, wherein
the ligands B are coordinated to a surface of the quantum dot,
each of the ligands A includes a hydrophilic moiety, a hydrophobic moiety, and a curable moiety, and
each of the ligands B includes a hydrophobic moiety.

2. The quantum dot-containing complex of claim 1, wherein the hydrophobic moieties of the ligands A and the hydrophobic moieties of the ligands B are bonded to each other via van der Waals forces.

3. The quantum dot-containing complex of claim 1, wherein the curable moieties of the ligands A are thermosetting moieties.

4. The quantum dot-containing complex of claim 1, wherein each ligand A is a compound in which the hydrophilic moiety, the curable moiety, and the hydrophilic moiety are bonded in this order.

5. The quantum dot-containing complex of claim 1, wherein the hydrophilic moiety, the hydrophilic moiety, and the curable moiety of each ligand A are linked to one another via SP³ carbon bonds.

6. The quantum dot-containing complex of claim 1, wherein the hydrophobic moieties of the ligands B are coordinated to the surface of the quantum dot.

7. The quantum dot-containing complex of claim 1, wherein the hydrophobic moieties of the ligands A are not coordinated to the surface of the quantum dot.

8. The quantum dot-containing complex of claim 1, wherein
the hydrophobic moieties of the ligands A face inward toward the quantum dot, and
the hydrophilic moieties of the ligands A face outward from the quantum dot, such that the ligands A form a micelle.

9. The quantum dot-containing complex of claim 1, wherein the curable moieties of the ligands A are covalently bonded to each other to form a single molecule.

10. The quantum dot-containing complex of claim 1, wherein the hydrophobic moiety of each ligand B has a length equal to or less than a length of the hydrophobic moiety of each ligand A.

11. The quantum dot-containing complex of claim 1, wherein the ligands A comprise a compound represented by one of Formulae 1 to 3: 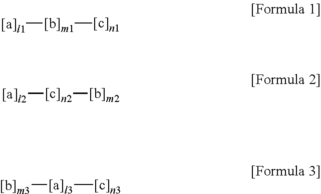
wherein in Formulae 1 to 3,
a is a group represented by Formula 1-1 or Formula 1-2, 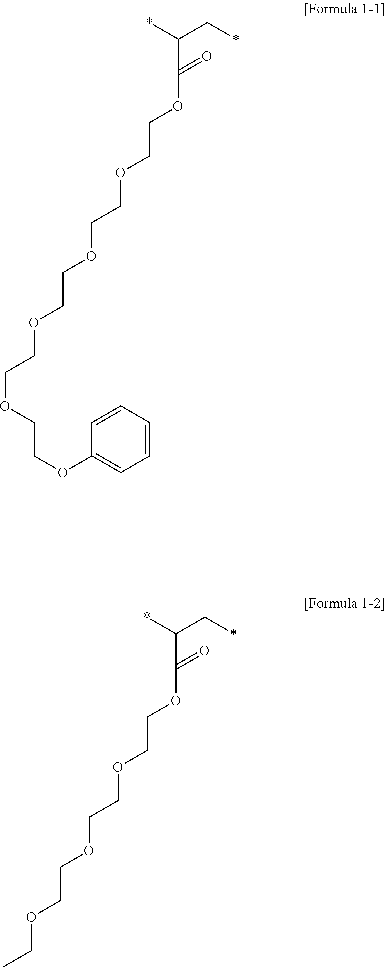 [SMILES: *CC(*)C(=O)OCCOCCOCCOCCOCCOc1ccccc1 ; *CC(*)C(=O)OCCOCCOCCOCC]
b is a group represented by Formula 2-1, 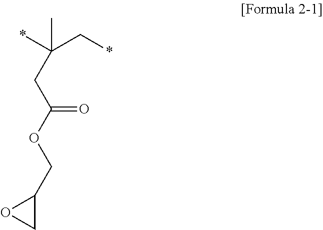 [SMILES: *CC(*)(C)CC(=O)OCC1CO1]
c is a group represented by Formula 3-1, Formula 3-2, or Formula 3-3, 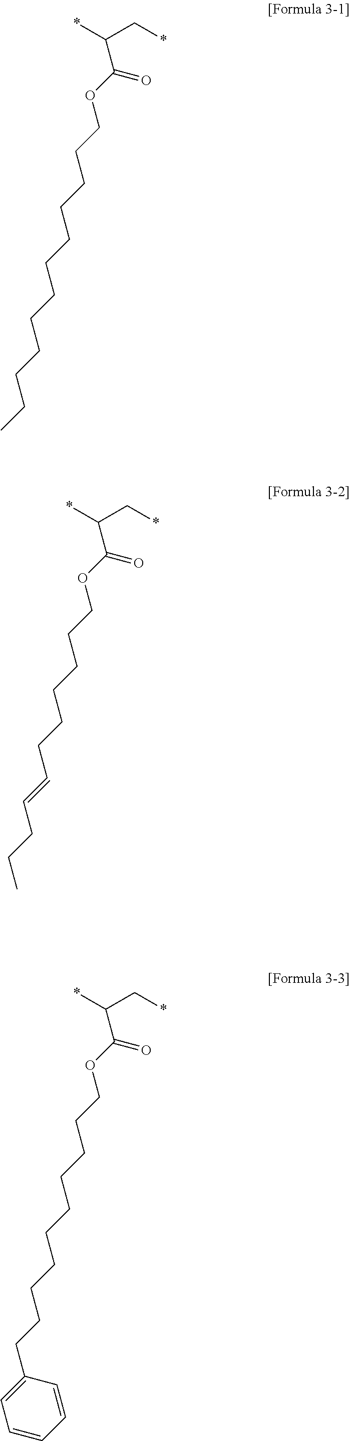 [SMILES: *CC(*)C(=O)OCCCCCCCCCCCC ; *CC(*)C(=O)OCCCCCC/C=C/CCC ; *CC(*)C(=O)OCCCCCCCCCCc1ccccc1]
I1 to I3, m1 to m3, and n1 to n3 are each independently an integer from 1 to 5,
when I1 is 2 or more, two or more of a in Formula 1 are identical to or different from each other,
when I2 is 2 or more, two or more of a in Formula 2 are identical to or different from each other,
when I3 is 2 or more, two or more of a in Formula 3 are identical to or different from each other,
when n1 is 2 or more, two or more of c in Formula 1 are identical to or different from each other,
when n2 is 2 or more, two or more of c in Formula 2 are identical to or different from each other,
when n3 is 2 or more, two or more of c in Formula 3 are identical to or different from each other, and
in Formulae 1-1, 1-2, 2-1, and 3-1 to 3-3, * denotes a bond, except that * at an end of a molecule denotes hydrogen.

12. The quantum dot-containing complex of claim 1, wherein the quantum dot has a core-shell structure comprising:
a core including a semiconductor compound; and
a shell including an oxide material, a semiconductor compound, or a combination thereof, and
the oxide material includes a metal oxide, a metalloid oxide, a non-metal oxide, or a combination thereof.

13. The quantum dot-containing complex of claim 12, wherein the semiconductor compound includes:
a Group II-VI semiconductor compound; a Group III-V semiconductor compound; a Group III-VI semiconductor compound; a Group I—III-VI semiconductor compound; a Group IV-VI semiconductor compound; a Group IV element or compound; or a combination thereof.

14. The quantum dot-containing complex of claim 12, wherein the oxide material includes SiO₂, Al₂O₃, TiO₂, ZnO, MnO, Mn₂O₃, Mn₃O₄, CuO, FeO, Fe₂O₃, Fe₃O₄, CoO, Co₃O₄, NiO, MgAl₂O₄, CoFe₂O₄, NiFe₂O₄, CoMn₂O₄, or a combination thereof.

15. The quantum dot-containing complex of claim 12, wherein the semiconductor compound includes CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP, GaS, GaSe, Ga₂Se₃, GaTe, InS, InSe, In₂S₃, In₂Se₃, InTe, InGaS₃, InGaSe₃, AgInS, AgInS₂, CuInS, CuInS₂, CuGaO₂, AgGaO₂, AgAlO₂, AgInGaS, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, SiGe, or a combination thereof.

16. The quantum dot-containing complex of claim 12, wherein the semiconductor compound in the shell includes CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or aa combination thereof.

17. A quantum dot composition comprising the quantum dot-containing complex of claim 1.

18. An electronic apparatus comprising the quantum dot-containing complex of claim 1.

19. The electronic apparatus of claim 18, further comprising:
a color filter and/or a color conversion layer, wherein
the color filter and/or the color conversion layer include the quantum dot-containing complex.

20. The electronic apparatus of claim 18, wherein the electronic apparatus comprises a light-emitting device comprising:
a first electrode;
a second electrode facing the first electrode; and
an interlayer between the first electrode and the second electrode,
the interlayer includes an emission layer, and
the emission layer includes the quantum dot-containing complex.
